(19) United States
(12) Patent Application Publication
(10) Pub. No.: US 2014/0225129 A1
(43) Pub. Date: Aug. 14, 2014

(54) ANTENNA MODULE AND METHOD FOR MANUFACTURING THE SAME

(71) Applicant: Nitto Denko Corporation, Osaka (JP)

(72) Inventors: Masami INOUE, Osaka (JP); Masayuki HODONO, Osaka (JP); Mitsuru HONJO, Osaka (JP)

(73) Assignee: Nitto Denko Corporation, Osaka (JP)

(21) Appl. No.: 14/177,815

(22) Filed: Feb. 11, 2014

(30) Foreign Application Priority Data
Feb. 12, 2013 (JP) 2013-024426

(51) Int. Cl. H01L 31/0232; H01L 31/12

(52) U.S. Cl. CPC H01L 31/02325; H01L 31/12
USPC 257/81; 438/25

(57) ABSTRACT

An electrode is formed on at least one surface of first and second surfaces of a dielectric film formed of resin to be capable of receiving or transmitting an electromagnetic wave in a terahertz band. A semiconductor device operable in the terahertz band is mounted on at least one surface of the first and second surfaces of the dielectric film to be electrically connected to the electrode. A portion of a support layer is formed on the first or second surface of the dielectric film, and a dielectric lens is supported by another portion of the support layer. Another portion of the support layer is bent with respect to the portion such that the electromagnetic wave in the terahertz band transmitted or received by the electrode permeates through the dielectric lens.

### BACKGROUND OF THE INVENTION

1. Field of the Invention

The present invention relates to an antenna module that transmits or receives an electromagnetic wave of a frequency in a tera hertz band not less than 0.05 THz and not more than 10 THz, for example.

2. Description of Related Art

Terahertz transmission using an electromagnetic wave in the terahertz band is expected to be applied to various purposes such as short-range super high speed communication and uncompressed delayless super high-definition video transmission.

In JP 2008-244620 A, a terahertz antenna module having a photoconductive antenna device is described. In the photoconductive antenna device, a pair of ohmic electrodes is formed at a GaAs layer on a semi-insulating GaAs substrate. A photoconductive antenna portion is formed by part of the pair of ohmic electrodes. This terahertz antenna module includes a rectangular parallelepiped base made of metal. A buffer member, a hemisphere-shaped lens, a photoconductive antenna device and a circuit board are arranged at a recess of the base in this order, and the circuit board, the photoconductive antenna device and the hemisphere-shaped lens are pressed against the buffer member by attachment of a cover member to the base.

### BRIEF SUMMARY OF THE INVENTION

The terahertz antenna module described in JP 2008-244620 A enables the terahertz wave to be transmitted in a direction vertical to the GaAs substrate from the photoconductive antenna portion through the hemispherical-shaped lens, and enables the terahertz wave that arrives in the direction vertical to the GaAs substrate to be received by the photoconductive antenna portion through the hemispherical-shaped lens.

However, a number of attachment members such as the base having a recess, the buffer member and the cover member are required in order to attach the hemisphere-shaped lens to the photoconductive antenna device. Therefore, a manufacturing cost of the terahertz antenna module increases, and an assembling process of the terahertz antenna module is complicated.

An object of the present invention is to provide an antenna module in which a manufacturing cost is reduced, and which can be easily assembled, and can improve a transmission speed and a transmission distance, and a method for manufacturing the antenna module.

(1) According to one aspect of the present invention, an antenna module includes a dielectric film that has first and second surfaces and is made of resin, an electrode formed on at least one surface of the first and second surfaces of the dielectric film to be capable of receiving and transmitting an electromagnetic wave in a terahertz band, a semiconductor device mounted on at least one surface of the first and second surfaces of the dielectric film to be electrically connected to the electrode and operable in the terahertz band, a support layer that has a first portion formed on the first or second surface of the dielectric film and has a second portion, and a lens supported by the second portion of the support layer, wherein the second portion is bent with respect to the first portion such that the electromagnetic wave transmitted or received by the electrode permeates through the lens.

The terahertz band indicates a range of frequencies of not less than 0.05 THz and not more than 10 THz, for example, and preferably indicates a range of frequencies of not less than 0.1 THz and not more than 1 THz.

In the antenna module, the electromagnetic wave in the terahertz band is transmitted or received by the electrode formed on at least one surface of the first and second surfaces of the dielectric film. Further, the semiconductor device mounted on at least one surface of the first and second surfaces of the dielectric film performs detection and rectification, or oscillation. The electromagnetic wave transmitted or received by the electrode is converged or paralleled by permeating through the lens.

The first portion of the support layer is formed on the first or second surface of the dielectric film, and the lens is supported by the second portion of the support layer. The second portion of the support layer is bent with respect to the first portion such that the electromagnetic wave in the terahertz band transmitted or received by the electrode permeates through the lens. In this case, it is possible to arrange the lens at a predetermined position with respect to the electrode by bending the support layer without using the plurality of attachment members. Therefore, a manufacturing cost of the antenna module is reduced, and the antenna module can be easily assembled.

Further, the dielectric film is formed of resin, so that an effective relative permittivity of the surroundings of the electrode is low. Thus, the electromagnetic wave radiated from the electrode or received by the electrode is less likely attracted to the dielectric film. Therefore, the antenna module can efficiently radiate the electromagnetic wave, and the better directivity of the antenna module is obtained.

Here, the transmission loss α [dB/m] of the electromagnetic wave is expressed in the following formula by a conductor loss α1 and a dielectric loss α2.

α=α1+α2[dB/m]

Letting ∈_{ref} be an effective relative permittivity, f be a frequency, R(f) be conductor surface resistance and tan δ be a dielectric tangent, the conductor loss α1 and the dielectric loss α2 are expressed as below.

α1∝R(f)·√∈_{ref}[dB/m]

α2∝√∈_{ref}·tan δ·f[dB/m]

From the above expressions, if the effective relative permittivity ∈_{ref} is low, the transmission loss α of the electromagnetic wave is reduced.

In the antenna module according to the present invention, because the effective relative permittivity of the surroundings of the electrode is low, the transmission loss of the electromagnetic wave is reduced. Thus, the transmission speed and the transmission distance can be improved. Further, the electromagnetic wave permeates through the lens, whereby the directivity and the antenna gain are improved.

(2) The second portion of the support layer may have a first opening through which the electromagnetic wave transmitted or received by the electrode passes; and the lens may be supported by the second portion to be positioned at the first opening.

In this case, the electromagnetic wave transmitted or received by the electrode permeates through the first opening of the support layer and the lens. Thus, the support layer can reliably support the lens without affecting the electromagnetic wave.

(3) The antenna module may further include an insulating layer formed on the second portion of the support layer to cover the first opening, wherein the lens may be formed on the insulating layer.

In this case, because the lens is formed on the insulating layer, the lens can be easily supported.

(4) The antenna module may further include a lens holding member that has a second opening and holds the lens to be positioned at the second opening, wherein the second portion of the support layer may support the lens holding member such that the electromagnetic wave transmitted or received by the electrode permeates through the lens.

In this case, the lens can be reliably and easily supported by the lens supporting member. Further, the electromagnetic wave transmitted or received by the electrode permeates through the second opening of the lens supporting member and the lens. Thus, the support layer can reliably support the lens without affecting the electromagnetic wave.

(5) A transmission direction or a receipt direction of the electromagnetic wave by the electrode may be parallel to the first and second surfaces of the dielectric film, and the second portion of the support layer may support the lens such that a light axis of the lens is parallel to the first and second surfaces of the dielectric film.

In this case, the lens is arranged such that the electromagnetic wave transmitted or received in a horizontal direction with respect to the first and second surfaces of the dielectric film by the electrode permeates through the lens. Thus, the electromagnetic wave can be transmitted or received in the horizontal direction with respect to the first and second surfaces of the dielectric film at the high directivity and the high antenna gain.

(6) The electrode may include first and second conductive layers that constitute a tapered slot antenna having a third opening, and the third opening may have a width that continuously or gradually decreases from one end to another end of a set of the first and second conductive layers.

In this case, the antenna module can transmit or receive the electromagnetic wave at various frequencies in the terahertz band. Thus, the transmission of an even larger bandwidth becomes possible. Further, because the tapered slot antenna has the directivity in a specific direction, the antenna module having the high directivity is realized.

(7) The support layer may be formed of a metal material, and the first portion of the support layer may be formed in a region that does not overlap with the electrode on the second surface.

In this case, even when the thickness of the dielectric film is small, the shape-retaining property of the antenna module is ensured. Thus, the transmission direction or the reception direction of the electromagnetic wave can be fixed. Further, the handleability of the antenna module is improved. Further, the change in directivity and the transmission loss of the electromagnetic wave due to the support body can be suppressed.

(8) According to another aspect of the present invention, a method for manufacturing an antenna module includes the steps of forming an electrode capable of receiving and transmitting an electromagnetic wave in a terahertz band on at least one surface of first and second surfaces of a dielectric film formed of resin, forming a first portion of a support layer that includes first and second portions on the first or second surface of the dielectric film, mounting a semiconductor device operable in the terahertz band on at least one surface of the first and second surfaces of the dielectric film to be electrically connected to the electrode, and providing a lens to be supported by the second portion of the support layer, and bending the second portion with respect to the first portion such that the electromagnetic wave transmitted or received by the electrode permeates through the lens.

The order of the formation process of the electrode at the dielectric film, the formation process of the support layer at the dielectric film and the mounting process of the semiconductor device is not limited.

In the method for manufacturing this antenna module, the first portion of the support layer is formed on the first or second surface of the dielectric film, and the lens is provided to be supported by the second portion of the support layer. Thereafter, the second portion of the support layer is bent with respect to the first portion such that the electromagnetic wave in the terahertz band transmitted or received by the electrode permeates through the lens. In this case, it is possible to arrange the lens at a predetermined position with respect to the electrode by bending the support layer without using the plurality of attachment members. Therefore, the manufacturing cost of the antenna module is reduced, and the antenna module can be easily assembled.

In the antenna module manufactured using this manufacturing method, the electromagnetic wave in the terahertz band can be transmitted or received by the electrode formed on at least one surface of the first and second surfaces of the dielectric film. Further, the semiconductor device mounted on at least one surface of the first and second surfaces of the dielectric film performs detection and rectification, or oscillation. The electromagnetic wave transmitted or received by the electrode is converged or paralleled by permeating through the lens.

Further, the dielectric film is made of resin, so that an effective relative permittivity of the surroundings of the electrode is low. Thus, the electromagnetic wave radiated from the electrode or received by the electrode is less likely attracted to the dielectric film. Therefore, the electromagnetic wave can be efficiently radiated, and better directivity of the antenna module is obtained. Further, because the effective relative permittivity of the surroundings of the electrode is low, the transmission loss of the electromagnetic wave is reduced. Thus, the transmission speed and the transmission distance can be improved. Further, the electromagnetic wave permeates through the lens, whereby the directivity and the antenna gain are improved.

(9) According to yet another aspect of the present invention, a method for manufacturing an antenna module includes the steps of forming an electrode capable of receiving or transmitting an electromagnetic wave in a terahertz band on at least one surface of first and second surfaces of a dielectric film formed of resin, forming a first portion of a support layer that includes first and second portions on the first or second surface of the dielectric film, mounting a semiconductor device operable in the terahertz band on at least one surface of the first and second surfaces of the dielectric film to be electrically connected to the electrode, bending the second portion with respect to the first portion, and providing a lens to be supported by the bent second portion, wherein the step of providing the lens includes arranging the lens such that the electromagnetic wave transmitted or received by the electrode permeates through the lens.

In the method for manufacturing this antenna module, the first portion of the support layer is formed on the first or second surface of the dielectric film, and the second portion of the support layer is bent with respect to the first portion. Thereafter, the lens is provided to be supported by the bent second portion. At this time, the lens is arranged such that the electromagnetic wave in the terahertz band transmitted or received by the electrode permeates through the lens. In this manner, it is possible to arrange the lens at a predetermined position with respect to the electrode by bending the support layer without using the plurality of attachment members. Therefore, the manufacturing cost for the antenna module is reduced, and the antenna module can be easily assembled.

In the antenna module manufactured using this manufacturing method, the electromagnetic wave in the terahertz band is transmitted or received by the electrode formed on at least one surface of the first and second surfaces of the dielectric film. Further, the semiconductor device mounted on at least one surface of the first and second surfaces of the dielectric film performs detection and rectification, or oscillation. The electromagnetic wave transmitted or received by the electrode is converged or paralleled by permeating the lens.

Further, because the dielectric film is formed of resin, the effective relative permittivity of the surroundings of the electrode is low. Thus, the electromagnetic wave radiated from the electrode or the electromagnetic wave received by the electrode is less likely attracted to the dielectric film. Therefore, the electromagnetic wave can be efficiently radiated, and the better directivity of the antenna module is obtained. Further, because the effective relative permittivity of the surroundings of the electrodes is low, the transmission loss of the electromagnetic wave is reduced. Thus, the transmission speed and the transmission distance can be improved. Further, the electromagnetic wave permeates through the lens, whereby the directivity and the antenna gain are improved.

The present invention enables the manufacturing cost of the antenna module to be reduced and the antenna module to be easily assembled, and the transmission speed and the transmission distance to be improved.

Other features, elements, characteristics, and advantages of the present invention will become more apparent from the following description of preferred embodiments of the present invention with reference to the attached drawings.

### BRIEF DESCRIPTION OF THE SEVERAL VIEWS OF THE DRAWING

FIG. 1 is an external perspective view of an antenna module according to a first embodiment;

FIG. 2 is a schematic side view of the antenna module of FIG. 1;

FIG. 3 is a schematic plan view of an antenna portion of FIG. 1;

FIG. 4 is a cross sectional view taken along the line A-A of the antenna portion of FIG. 3;

FIG. 5 is a schematic diagram showing the mounting of a semiconductor device using a flip chip mounting method;

FIG. 6 is a schematic diagram showing the mounting of the semiconductor device using a wire-bonding mounting method;

FIG. 7 is a schematic plan view of a support body of FIG. 1;

FIG. 8 is a schematic plan view of a support layer of the support body of FIG. 7;

FIG. 9 is a schematic plan view of the antenna module before the support layer is bent;

FIGS. 10(a) and 10(b) are schematic sectional views showing the steps for manufacturing the antenna module of FIG. 9;

FIGS. 11(a) and 11(b) are schematic sectional views showing the steps for manufacturing the antenna module of FIG. 9;

FIGS. 12(a) and 12(b) are schematic sectional views showing the steps for manufacturing the antenna module of FIG. 9;

FIG. 13 is a schematic plan view showing the reception operation of the antenna portion;

FIG. 14 is a schematic plan view showing the transmission operation of the antenna portion;

FIG. 15 is a schematic side view for explaining the directivity of the antenna portion;

FIG. 16 is a schematic side view for explaining the change in directivity of the antenna portion;

FIG. 17 is an external perspective view of the antenna module according to the second embodiment;

FIG. 18 is a schematic side view of the antenna module of FIG. 17;

FIG. 19 is a schematic plan view of the support layer of the support body of FIG. 17;

FIGS. 20(a) to 20(c) are diagrams showing the configuration of a lens holding member of the support body of FIG. 17;

FIG. 21 is a schematic plan view for explaining the dimensions of the antenna portion of the antenna module used in the electromagnetic field simulation;

FIG. 22 is a schematic diagram for explaining the definition of the reception angle of the antenna portion in the simulation;

FIGS. 23(a) and 23(b) are diagrams showing the results of the three-dimensional electromagnetic field simulation of the antenna module;

FIG. 24 is a plan view showing the configuration of the antenna module according to an inventive example;

FIG. 25 is a diagram showing the simulation results of the antenna gain of the antenna module according to the inventive examples 1 to 3 and the comparative example 1;

FIG. 26 is a diagram showing the simulation results of the antenna gain of the antenna module according to the inventive examples 1 to 3 and the comparative example 1;

FIG. 27(a) is a diagram showing the results of the three-dimensional electromagnetic field simulation of the antenna module according to the inventive example 1;

FIG. 27(b) is a diagram showing the results of the three-dimensional electromagnetic field simulation of the antenna module according to the inventive example 2;

FIG. 28(a) is a diagram showing the results of the three-dimensional electromagnetic field simulation of the antenna module according to the inventive example 3;

FIG. 28(b) is a diagram showing the results of the three-dimensional electromagnetic field simulation of the antenna module according to the comparative example 1;

FIG. 29 is a diagram showing the simulation results of the antenna gain of the antenna module according to the inventive examples 4,5 and the comparative example 2;

FIG. 30 is a diagram showing the simulation results of the antenna gain of the antenna module according to the inventive examples 4,5 and the comparative example 2;

FIG. 31 is a diagram showing the simulation results of the electric field distribution of the electromagnetic wave radiated by the antenna module according to the inventive example 4;

FIG. 32 is a diagram showing the simulation results of the electric field distribution of the electromagnetic wave radiated by the antenna module according to the inventive example 5;

FIG. 33 is a diagram showing the simulation results of the electric field distribution of the electromagnetic wave radiated by the antenna module according to the comparative example 3;

FIG. 34 is a diagram showing the simulation results of the electric field distribution of the electromagnetic wave radiated by the antenna module according to the comparative example 4;

FIG. 35 is a diagram showing the results of the electromagnetic field simulation of the antenna gain of the antenna module according to the inventive examples 6, 7 and the comparative example 5;

FIG. 36 is a diagram showing the results of the electromagnetic field simulation of the antenna gain of the antenna module according to the inventive examples 6, 7 and the comparative example 5;

FIG. 37 is a diagram showing the simulation results of the electric field distribution of the electromagnetic wave radiated by the antenna module according to the inventive example 6;

FIG. 38 is a diagram showing the simulation results of the electric field distribution of the electromagnetic wave radiated by the antenna module according to the inventive example 7;

FIG. 39 is a diagram showing the simulation results of the electric field distribution of the electromagnetic wave radiated by the antenna module according to the comparative example 6;

FIG. 40 is a diagram showing the results of the electromagnetic field simulation of the antenna gain of the antenna module according to the inventive examples 8 to 10 and the comparative example 7;

FIG. 41 is a diagram showing the results of the electromagnetic field simulation of the antenna gain of the antenna module according to the inventive examples 8 to 10 and the comparative example 7;

FIG. 42 is a diagram showing the simulation results of the electric field distribution of the electromagnetic wave radiated by the antenna module according to the inventive example 9;

FIG. 43 is a diagram showing the results of the electromagnetic field simulation of the antenna gain of the antenna module according to the inventive examples 11, 12; and

FIG. 44 is a diagram showing the results of the electromagnetic field simulation of the antenna gain of the antenna module according to the inventive examples 11, 12.

### DESCRIPTION OF THE PREFERRED EMBODIMENTS

An antenna module and a method for manufacturing the antenna module according to embodiments of the present invention will be described below. In the following description, a frequency band from 0.05 THz to 10 THz is referred to as a terahertz band. The antenna module according to the present embodiment can receive or transmit an electromagnetic wave having at least a specific frequency in the terahertz band.

### [1] First Embodiment

### (1) Configuration of Antenna Module

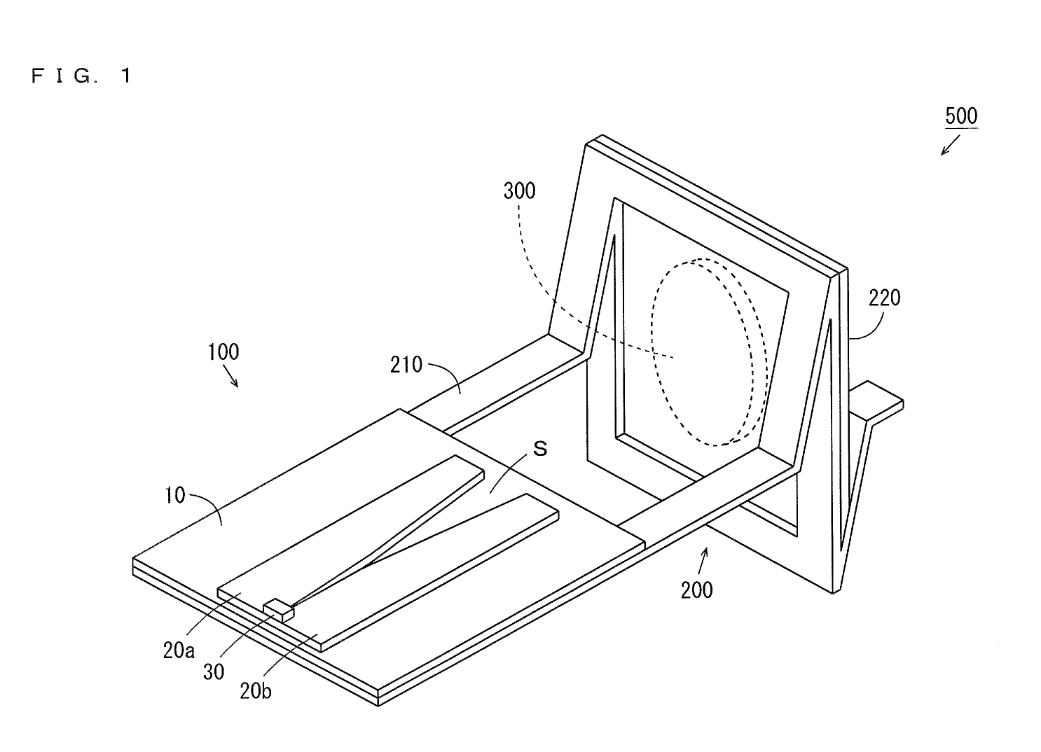

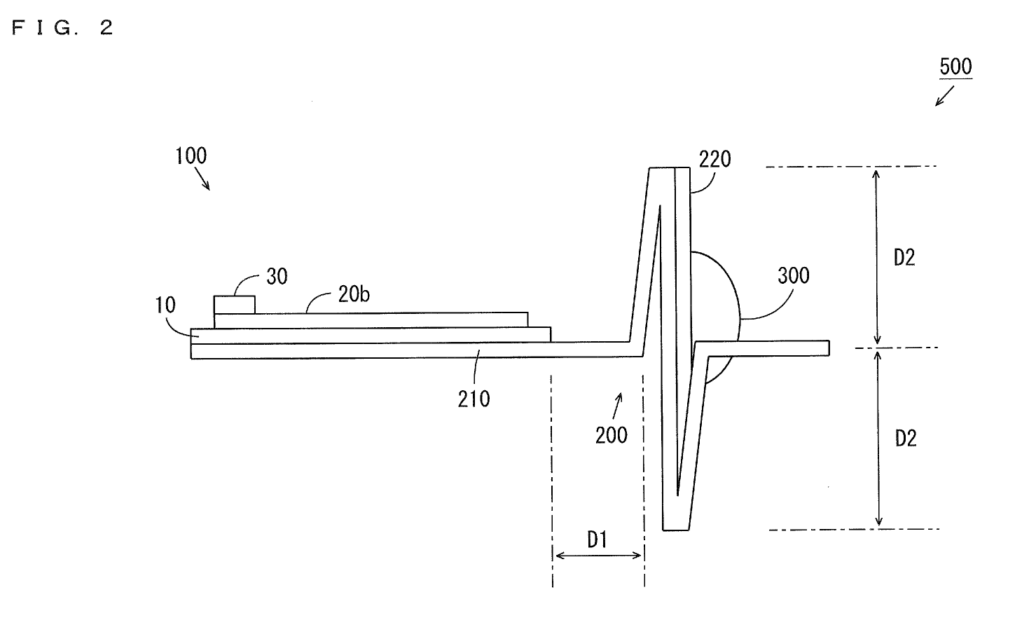

FIG. 1 is an external perspective view of the antenna module according to the first embodiment. FIG. 2 is a schematic side view of the antenna module of FIG. 1. As shown in FIGS. 1 and 2, the antenna module 500 includes an antenna portion 100, a support body 200 and a dielectric lens 300. Details of the antenna portion 100, the support body 200 and the dielectric lens 300 will be described below.

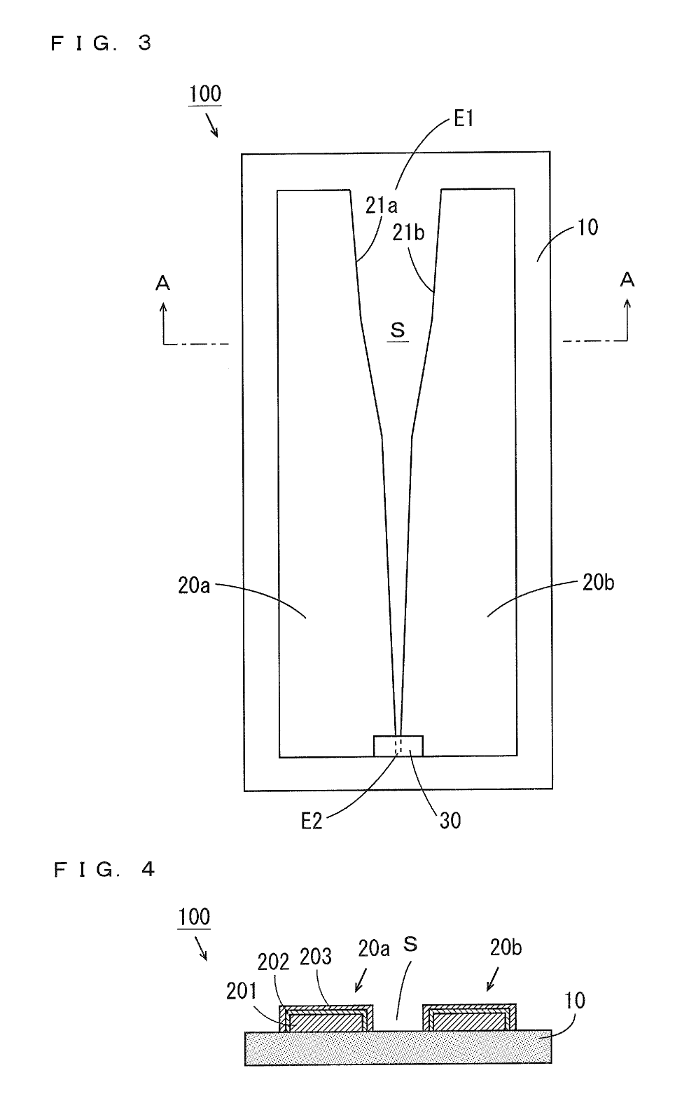

FIG. 3 is a schematic plan view of the antenna portion 100 of FIG. 1. FIG. 4 is a cross sectional view taken along the line A-A of the antenna portion 100 of FIG. 3. As shown in FIGS. 3 and 4, the antenna portion 100 is constituted by a dielectric film 10, a pair of electrodes 20a, 20b and a semiconductor device 30. The dielectric film 10 is formed of resin that is made of polymer. One surface of the two surfaces of the dielectric film 10 opposite to each other is referred to as a main surface, and the other surface is referred to as a back surface.

The pair of electrodes 20a, 20b is formed on the main surface of the dielectric film 10. A gap that extends from one end to the other end of a set of the electrodes 20a, 20b is provided between the electrodes 20a, 20b. End surfaces 21a, 21b of the electrodes 20a, 20b that face each other are formed in a tapered shape such that the width of the gap continuously or gradually decreases from the one end to the other end of a set of the electrodes 20a, 20b. The gap between the electrodes 20a, 20b is referred to as a tapered slot S. The electrodes 20a, 20b constitute a tapered slot antenna.

In this case, the antenna module 500 can transmit or receive the electromagnetic wave at various frequencies in the terahertz band. Thus, transmission of an even larger bandwidth becomes possible. Further, because the tapered slot antenna has directivity in a specific direction, the antenna module 500 having the high directivity can be realized.

The dielectric film 10 and the electrodes 20a, 20b are formed of a flexible printed circuit board. In this case, the electrodes 20a, 20b are formed on the dielectric film 10 using a subtractive method, an additive method or a semi-additive method. If a below-mentioned semiconductor device 30 is appropriately mounted, the electrodes 20a, 20b may be formed on the dielectric film 10 using another method. For example, the electrodes 20a, 20b may be formed by patterning a conductive material on the dielectric film 10 using a screen printing method, an ink-jet method or the like.

Here, the dimension in the direction of a central axis of the tapered slot S is referred to as length, and the dimension in the direction parallel to the main surface of the dielectric film 10 and orthogonal to the central axis of the tapered slot S is referred to as width. The end of the tapered slot S having the maximum width is referred to as an opening end E1, and the end of the tapered slot S having the minimum width is referred to as a mount end E2. Further, a direction directed from the mount end E2 toward the opening end E1 of an antenna portion 100 and extends along the central axis of the tapered slot S is referred to as a central axis direction.

The semiconductor device 30 is mounted on the ends of the electrodes 20a, 20b at the mount end E2 using a flip chip mounting method or a wire bonding mounting method. One terminal of the semiconductor device 30 is electrically connected to the electrode 20a, and another terminal of the semiconductor device 30 is electrically connected to the electrode 20b. The mounting method of the semiconductor device 30 will be described below. The electrode 20b is to be grounded.

As the material for the dielectric film 10, one or more types of porous resins or non-porous resins out of polyimide, polyetherimide, polyamide-imide, polyolefin, cycloolefin polymer, polyarylate, polymethyl methacrylate polymer, liquid crystal polymer, polycarbonate, polyphenylene sulfide, polyether ether ketone, polyether sulfone, polyacetal, fluororesin, polyester, epoxy resin, polyurethane resin and urethane acrylic resin (acryl resin) can be used.

Fluororesin includes polytetrafluoroethylene (PTFE), polyvinylidene fluoride, ethylene-tetrafluoroethylene copolymer, perfluoro-alkoxy fluororesin, fluorinated ethylene-propylene copolymer (tetrafluoroethylene-hexafluoropropylene copolymer) or the like. Polyester includes polyethylene terephthalate, polyethylene naphthalate, polybutylene terephthalate or the like.

In the present embodiment, the dielectric film 10 is formed of polyimide. The thickness of the dielectric film 10 is preferably not less than 1 μm and not more than 1000 μm. In this case, the dielectric film 10 can be easily fabricated and flexibility of the dielectric film 10 can be easily ensured. The thickness of the dielectric film 10 is more preferably not less than 5 μm and not more than 100 μm. In this case, the dielectric film 10 can be more easily fabricated and higher flexibility of the dielectric film 10 can be easily ensured.

The dielectric film 10 preferably has a relative permittivity of not more than 7.0, and more preferably has a relative permittivity of not more than 4.0, in a used frequency within the terahertz band. In this case, the radiation efficiency of an electromagnetic wave having the used frequency is sufficiently increased and the transmission loss of the electromagnetic wave is sufficiently reduced. Thus, the transmission speed and the transmission distance of the electromagnetic wave having the used frequency can be sufficiently improved. In the present embodiment, the dielectric film 10 is formed of resin having a relative permittivity of not less than 1.2 and not more than 7.0 in the terahertz band. The relative permittivity of polyimide is about 3.2 in the terahertz band, and the relative permittivity of porous polytetrafluoroethylene (PTFE) is about 1.2 in the terahertz band.

The electrodes 20a, 20b may be formed of a conductive material such as metal or an alloy, and may have single layer structure or laminate structure of a plurality of layers.

In the present embodiment, as shown in FIG. 4, each of the electrodes 20a, 20b has the laminate structure of a copper layer 201, a nickel layer 202 and a gold layer 203. The thickness of the copper layer 201 is 15 μm, for example, the thickness of the nickel layer 202 is 3 μm, for example and the thickness of the gold layer 203 is 0.2 μm, for example. The material and the thickness of the electrodes 20a, 20b are not limited to the examples of the present embodiment.

In the present embodiment, the laminate structure of FIG. 4 is adopted to perform the flip chip mounting by Au stud bumps and a wire bonding mounting by Au bonding wires, mentioned below. Formation of the nickel layer 202 and the gold layer 203 is surface processing for the copper layer 201 in a case in which the afore-mentioned mounting methods are used. When another mounting method using solder balls, ACFs (anisotropic conductive films), ACPs (anisotropic conductive pastes) or the like are used, processing appropriate for respective mounting method is selected.

One or plurality of semiconductor devices selected from a group consisting of a resonant tunneling diode (RTD), a Schottky-barrier diode (SBD), a TUNNETT (Tunnel Transit Time) diode, an IMPATT (Impact Ionization Avalanche Transit Time) diode, a high electron mobility transistor (HEMT), a GaAs field effect transistor (FET), a GaN field effect transistor (FET) and a Heterojunction Bipolar Transistor (NBT) is used as the semiconductor device 30. These semiconductor devices are active elements. A quantum element, for example, can be used as the semiconductor device 30. In the present embodiment, the semiconductor device 30 is a Schottky-barrier diode.

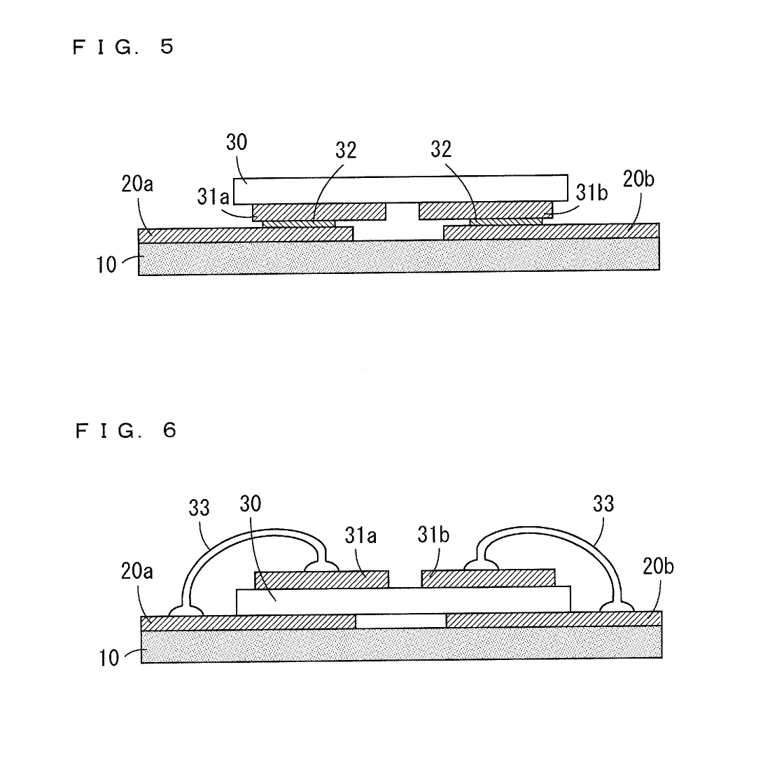

FIG. 5 is a schematic diagram showing the mounting of the semiconductor device 30 using the flip chip mounting method. As shown in FIG. 5, the semiconductor device 30 has terminals 31a, 31b. The terminals 31a, 31b are an anode and a cathode of a diode, for example. The semiconductor device 30 is positioned above the electrodes 20a, 20b such that the terminals 31a, 31b are directed downward, and the terminals 31a, 31b are bonded to the electrodes 20a, 20b using Au stud bumps 32, respectively.

FIG. 6 is a schematic diagram showing the mounting of the semiconductor device 30 using the wire bonding mounting method. As shown in FIG. 6, the semiconductor device 30 is positioned on the electrodes 20a, 20b such that the terminals 31a, 31b are directed upward, and the terminals 31a, 31b are connected to the electrodes 20a, 20b respectively using Au bonding wires 33.

In the antenna portion 100 of FIG. 3, an area from the opening end E1 of the taper slot S to the mount portion for the semiconductor device 30 functions as a transmitter/receiver that transmits or receives the electromagnetic wave. The frequency of the electromagnetic wave transmitted or received by the antenna portion 100 is determined by the width of the taper slot S and an effective relative permittivity of the tapered slot S. The effective relative permittivity of the tapered slot S is calculated based on a relative permittivity of the air between the electrodes 20a, 20b, and the relative permittivity and the thickness of the dielectric film 10.

Generally, a wavelength λ of the electromagnetic wave in a medium is expressed in the following formula.

λ=λ₀/√∈_{ref}

λ₀ is a wavelength of the electromagnetic wave in a vacuum, and ∈_{ref} is an effective relative permittivity of the medium. Therefore, if the effective relative permittivity of the tapered slot S increases, a wavelength of the electromagnetic wave in the tapered slot S is shortened. In contrast, if the effective relative permittivity of the tapered slot S decreases, a wavelength of the electromagnetic wave in the tapered slot S is lengthened. When the effective relative permittivity of the tapered slot S is assumed to be minimum 1, the electromagnetic wave of 0.1 THz is transmitted or received at a portion where the width of the tapered slot S is 1.5 mm. The tapered slot S preferably includes a portion having the width of 2 mm in consideration of a margin.

The length of the tapered slot S is preferably not less than 0.5 mm and not more than 30 mm. A mount area for the semiconductor device 30 can be ensured when the length of the tapered slot S is not less than 0.5 mm. Further, the length of the tapered slot S is preferably not more than 30 mm on the basis of ten times of the wavelength.

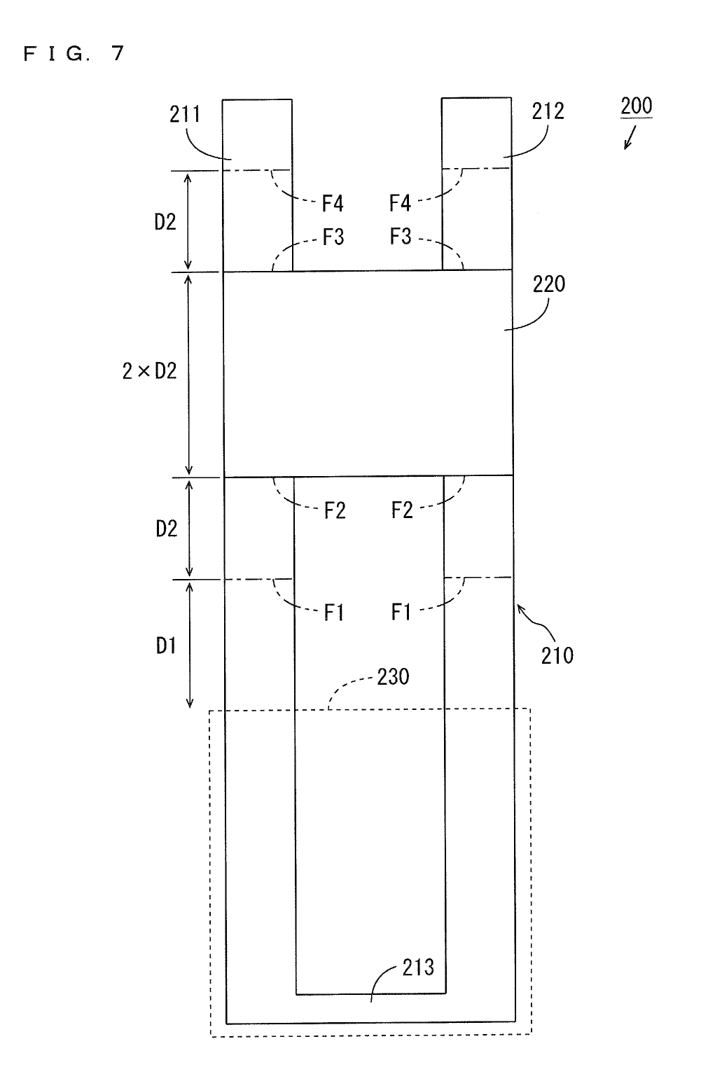

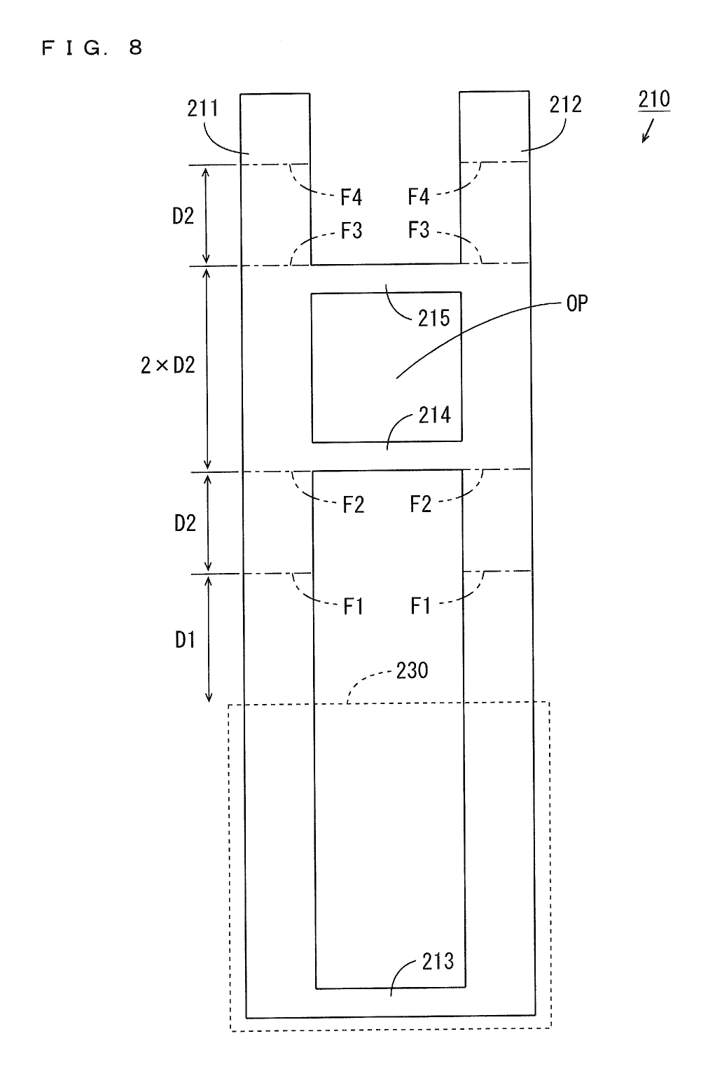

FIG. 7 is a schematic plan view of the support body 200 of FIG. 1. FIG. 8 is a schematic plan view of a support layer of the support body 200 of FIG. 7. As shown in FIG. 7, the support body 200 includes a support layer 210 and an insulating layer 220.

The support layer 210 is formed of material that is bendable and has a shape-retaining property. In the present embodiment, the support layer 210 is a metal layer formed of stainless. The support layer 210 may be formed of another metal such as aluminum or copper. Further, in the present embodiment, the insulating layer 220 is formed of a dielectric that hardly absorbs the electromagnetic wave of not less than 0.1 THz and not more than 0.5 THz.

The insulating layer 220 may be formed of the same resin material as the dielectric film 10. In the present embodiment, the insulating layer 220 is formed of polyimide. In a case in which the insulating layer 220 is formed of the same resin material as the dielectric film 10, the insulating layer 220 may be a dielectric film that is joined to the dielectric film 10. In this case, the dielectric film is bent.

The insulating layer 220 may be formed of another insulator that hardly absorbs the electromagnetic wave in the terahertz band that is received or transmitted by the antenna portion 100 of FIG. 3. For example, the insulating layer 220 may be formed of porous PTFE.

As shown in FIG. 8, the support layer 210 includes a plurality (two in the present example) of strip-shaped support plates 211, 212, and a plurality (three in the present example) of reinforcement plates 213, 214, 215. The support plates 211, 212 are provided to be parallel to each other. The reinforcement plate 213 is integrally formed at the support plates 211, 212 to connect the one end of a set of the support plates 211, 212 in the longitudinal direction.

The reinforcement plate 214 is integrally formed at a set of the support plates 211, 212 to connect a portion of the support plate 211 and a portion of the support plate 212. The reinforcement plate 215 is integrally formed at a set of the support plates 211, 212 to connect another portion of the support substrate 211 and another portion of the support plate 212. A rectangular opening OP is formed by the support plates 211, 212 and the reinforcement plates 214, 215. The rectangular insulating layer 220 of FIG. 7 is formed on the support plates 211, 212 and the reinforcement plates 214, 215 so as to close the opening OP.

One surface of the two surfaces of the support layer 210 opposite to each other is referred to as a main surface, and the other surface is referred to as a back surface. An antenna portion arrangement region 230 in which the antenna portion 100 of FIG. 3 is arranged is provided on the main surface of the reinforcement plate 213 and portions of the support plates 211, 212 having a constant length of the support layer 210. In FIGS. 7 and 8, the antenna portion arrangement region 230 is indicated by the dotted line.

A plurality (four in the examples of FIGS. 7 and 8) of bent portions F1, F2, F3, F4 that are parallel to the width direction are provided at the support layer 210. In FIGS. 7 and 8, the bent portions F1 to F4 are indicated by the one-dot dash line. The distance between the end of the antenna portion arrangement region 230 and the bent portion F1 is set to D1. The distance between the bent portions F1, F2 is set to D2. The distance between the bent portions F2, F3 is set to 2×D2. The distance between the bent portions F3, F4 is set to D2.

The bent portions F1 to F4 may be shallow line grooves, or a line mark or the like, for example. Alternatively, if the support layer 210 is bendable at the bent portions F1 to F4, nothing in particular may be at the bent portions F1 to F4. In the present example, the bent portions F1 to F4 are shallow line grooves provided at the main surface of the support layer 210. Hereinafter, bending the support layer 210 such that the back surfaces of the support layer 210 face each other is referred to as mountain fold, and bending the support layer 210 such that the main surfaces of the support layer 210 face each other is referred to as valley fold.

In this manner, the support layer 210 is formed of a metal material, and the support plates 211, 212 of the support layer 210 are formed in a region that does not overlap with the electrodes 20a, 20b on the back surface of the dielectric film 10. In this case, even when the thickness of the dielectric film 10 is small, the shape-retaining property of the antenna module 500 is ensured. Thus, the transmission direction or the receipt direction of the electromagnetic wave can be fixed. Further, handleability of the antenna module 500 is improved. Further, the change in directivity due to the support body and the transmission loss of the electromagnetic wave can be suppressed.

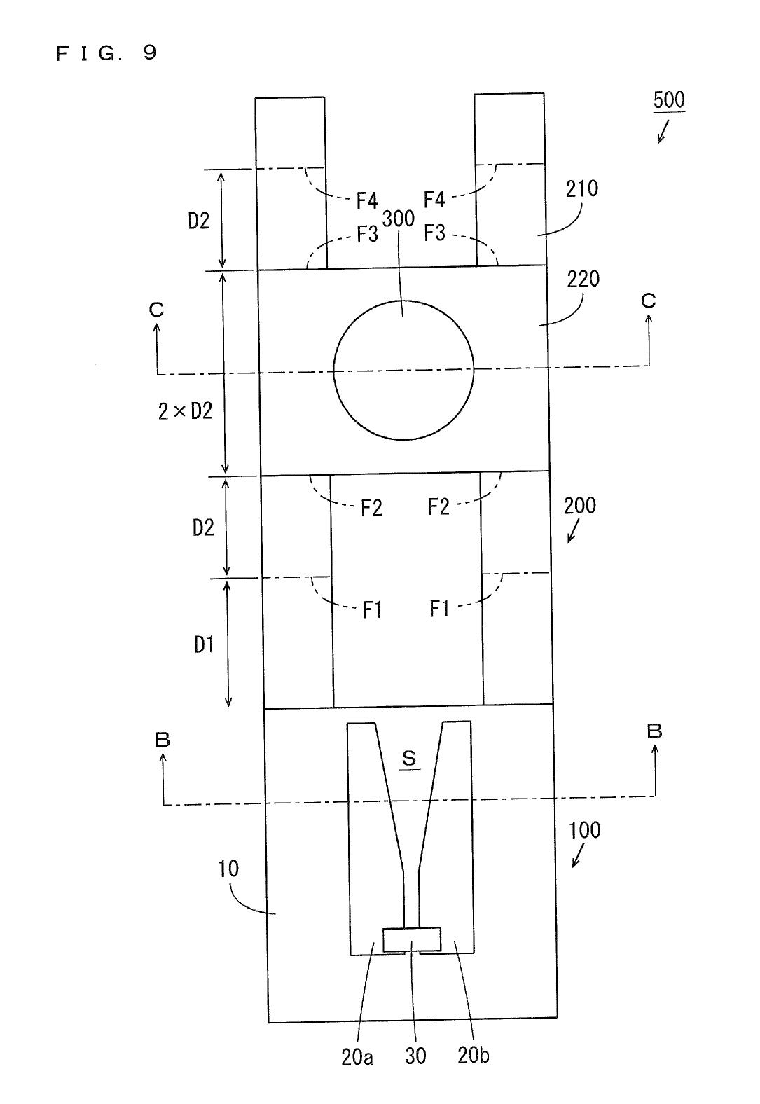

FIG. 9 is a schematic plan view of the antenna module 500 before the support layer 210 is bent. As shown in FIG. 9, the antenna portion 100 is arranged on the antenna portion arrangement region 230 of FIG. 7. Further, the dielectric lens 300 is formed on the insulating layer 220 to overlap with the opening OP of FIG. 8. In the present example, the dielectric lens 300 is a plane-convex lens, and is formed of PTFE having a relative permittivity of 2.1.

The support layer 210 is bent to form the mountain fold along the bent portions F2, F4, and the support layer 210 is bent to form the valley fold along the bent portions F1, F3. Thus, as shown in FIG. 1, the insulating layer 220 is vertical to the main surface of the dielectric film 10. Here, as shown in FIG. 2, the distance between the bent portions F1, F2 is D2, the distance between the bent portions F2, F3 is 2×D2 and the distance between the bent portions F3, F4 is D2. This configuration causes the center of the opening OP and the center of the insulating layer 220 of FIG. 8 to be positioned on the same plane as the support layer 210.

The dielectric lens 300 is formed on the insulating layer 220 such that a light axis passes through the tapered slot S of the antenna portion 100 and overlaps with the opening OP of FIG. 8. The dielectric lens 300 is arranged at a position spaced apart from the antenna portion 100 substantially by the distance D1.

This configuration causes the electromagnetic wave in the terahertz band transmitted by the antenna portion 100 to be radiated through the insulating layer 220 and the dielectric lens 300. In this case, the electromagnetic wave is paralleled by the dielectric lens 300. Further, the electromagnetic wave in the terahertz wave is received by the antenna portion 100 through the dielectric lens 300 and the insulating layer 220. In this case, the electromagnetic wave is converged by the dielectric lens 300.

Because the dielectric lens 300 is formed on the insulating layer 220, the dielectric lens 300 can be easily supported. Further, the electromagnetic wave transmitted or received by the electrodes 20a, 20b permeates through the opening OP of the support layer 210 and the dielectric lens 300. Thus, the dielectric lens 300 can be reliably supported with the support layer 210 not affecting the electromagnetic wave.

### (2) Method for Manufacturing Antenna Module

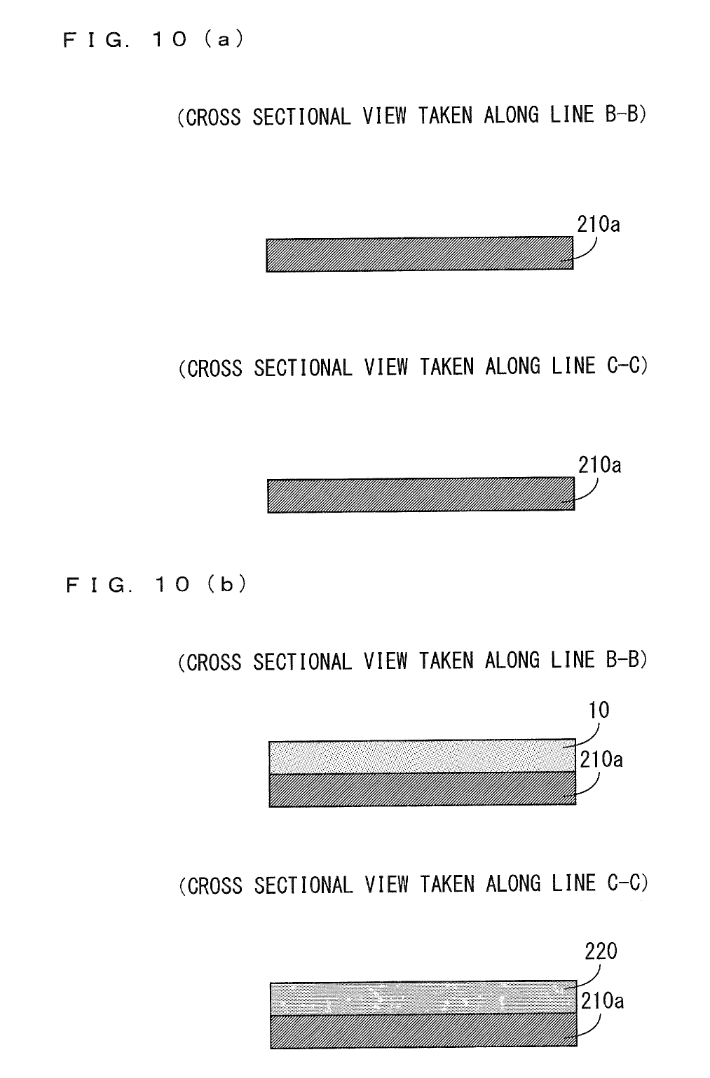

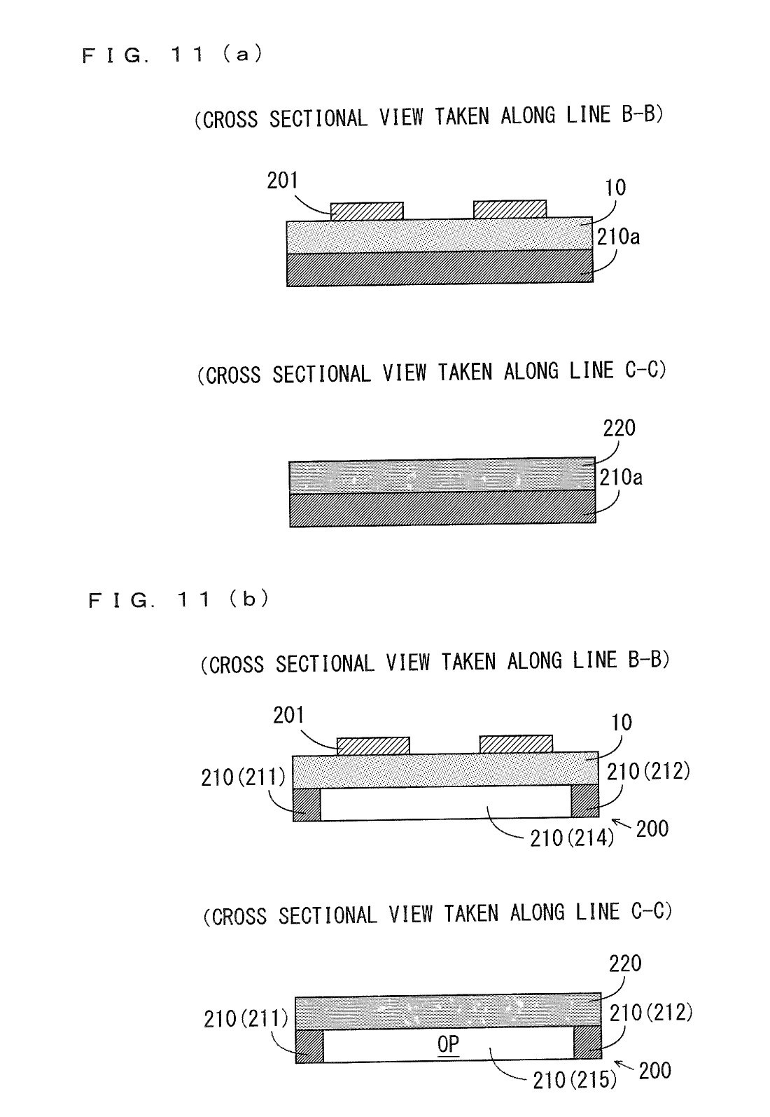

A manufacturing process for the antenna module 500 of FIG. 9 will be described. FIGS. 10(a) to 12(b) are sectional views showing the steps for manufacturing the antenna module 500 of FIG. 9. The upper diagrams in FIGS. 10(a), 10(b) to 12(a) and 12(b) show cross sectional views taken along the line B-B of the antenna module 500 of FIG. 9. The lower diagrams in FIGS. 10(a), 10(b) to 12(a), 12(b) show cross sectional views taken along the line C-C of the antenna module 500 of FIG. 9.

First, as shown in FIG. 10(a), a long-sized metal layer 210a made of stainless steel, for example, is prepared. The thickness of the metal layer 210a is 50 μm, for example. Here, shallow line grooves are respectively formed at predetermined four positions at the main surface of the metal layer 210a by half-etching, for example. Thus, the bent portions F1 to F4 are formed at the metal layer 210a.

The shallow line grooves may be formed at the back surface of the metal layer 210a. Alternatively, the shallow grooves that correspond to the bent portions F1, F3 for the valley fold may be formed at the main surface of the metal layer 210a, and the shallow grooves that correspond to the bent portions F2, F4 for the mountain fold may be formed at the back surface of the metal layer 210a.

Next, as shown in FIG. 10(b), the dielectric film 10 is formed at a predetermined position on the main surface of the metal layer 210a, and the insulating layer 220 is formed at another predetermined position on the main surface of the metal layer 210a. For example, a polyimide resin precursor is heated after the polyimide resin precursor is applied on the main surface of the metal layer 210a, whereby the dielectric film 10 and the insulating layer 220 can be formed. In the present example, the thickness of the dielectric film 10 is 25 μm, for example, and the thickness of the insulating layer 220 is 20 μm, for example.

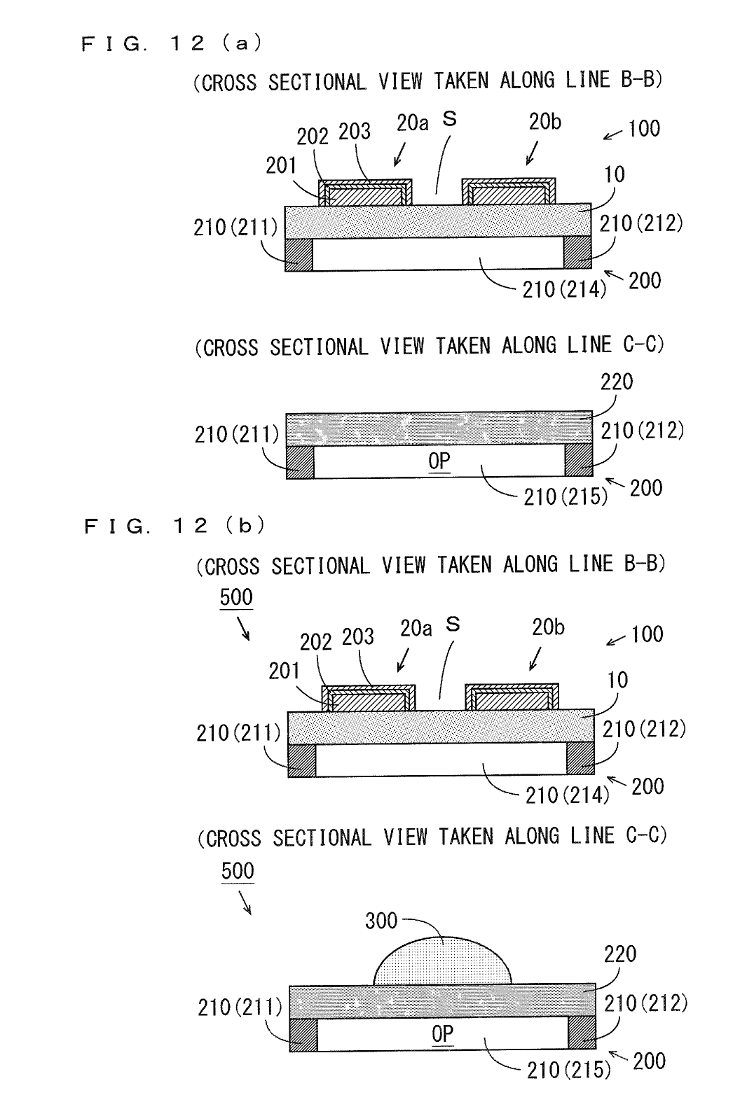

Subsequently, as shown in FIG. 11(a), the copper layer 201 is formed on the dielectric film 10. The copper layer 201 can be formed using a semi-additive method, for example.

Thereafter, as shown in FIG. 11(b), the metal layer 210a is processed, whereby the support layer 210 having the support plates 211, 212, the reinforcement plates 214, 215 and the reinforcement plate 213 of FIG. 8 are formed. The support layer 210 can be formed by wet-etching using a photoresist mask having a predetermined pattern and a ferric chloride solution, for example. A rectangular region surrounded by the support plates 211, 212 and the reinforcement plates 214, 215 becomes the opening OP. Thus, the support body 200 is completed.

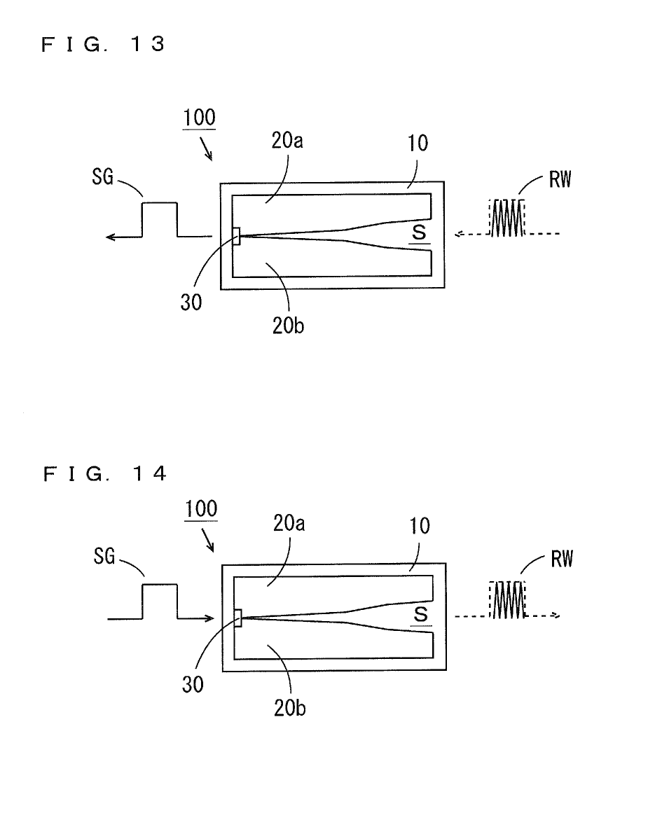

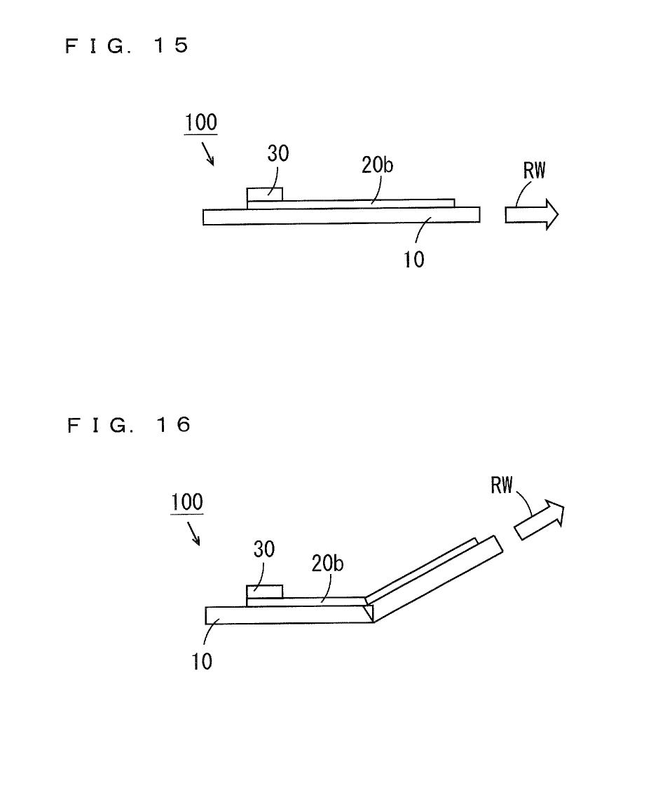

Next, as shown in FIG. 12(a), the nickel layer 202 and the gold layer 203 are sequentially formed to cover the copper layer 201. The nickel layer 202 can be formed by nickel plating, for example, and the gold layer 203 can be formed by gold plating, for example. The electrodes 20a, 20b are formed by the copper layer 201, the nickel layer 202 and the gold layer 203. The gap between a set of the electrodes 20a, 20b becomes the tapered slot S. The semiconductor device 30 of FIG. 3 is mounted on the end of a set of electrodes 20a, 20b, whereby the antenna portion 100 is completed.

Finally, as shown in FIG. 12(b), the dielectric lens 300 is formed on the insulating layer 220. The dielectric lens 300 can be formed on the insulating layer 220 using any process such as a mold, an ink-jet method or a dispenser. Here, the dielectric lens 300 is formed with an alignment mark formed of copper, for example, used as a basis, whereby the dielectric lens 300 can be accurately arranged with respect to the antenna portion 100. The alignment mark may be simultaneously formed with the copper layer 201 in the process of FIG. 11(a). In this manner, the antenna module 500 is completed.

### (3) Operation of Antenna Portion

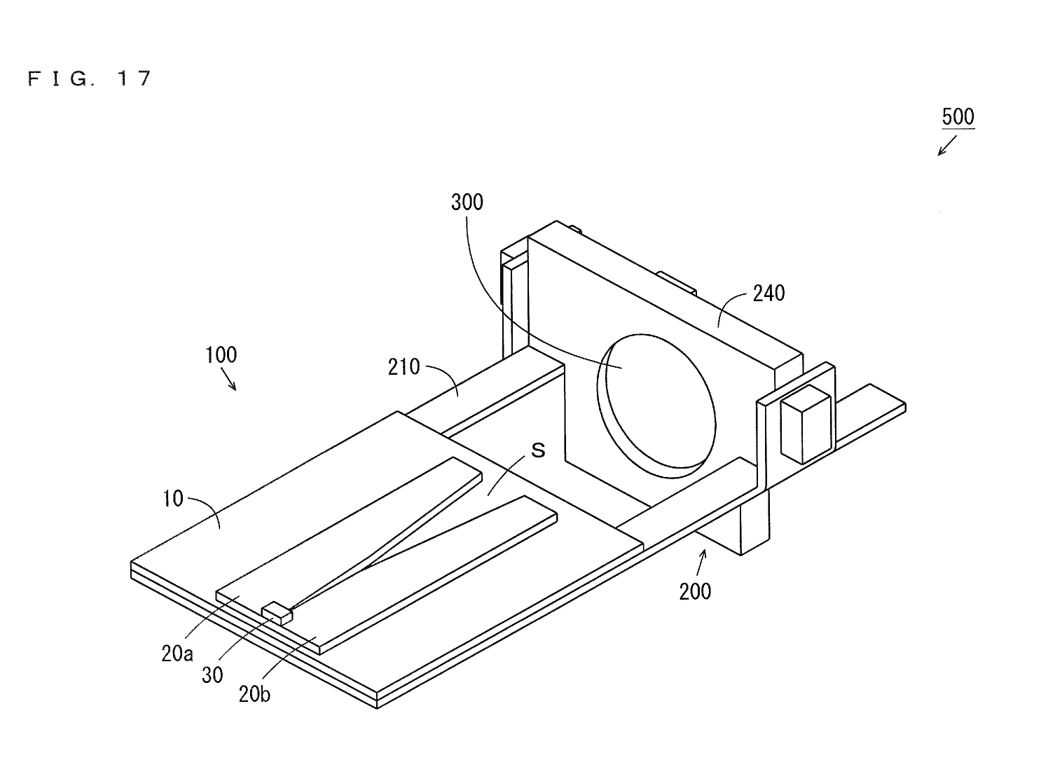

FIG. 13 is a schematic plan view showing the reception operation of the antenna portion 100. In FIG. 13, an electromagnetic wave RW includes a digital intensity modulated signal wave having a frequency (0.3 THz, for example) in the terahertz band and a signal wave having a frequency (1 GHz, for example) in a gigahertz band. The electromagnetic wave RW is received in the tapered slot S of the antenna portion 100. Thus, an electric current having a frequency component in the terahertz band flows in the electrodes 20a, 20b. The semiconductor device 30 performs detection and rectification. Thus, a signal SG having a frequency (1 GHz, for example) in the gigahertz band is output from the semiconductor device 30.

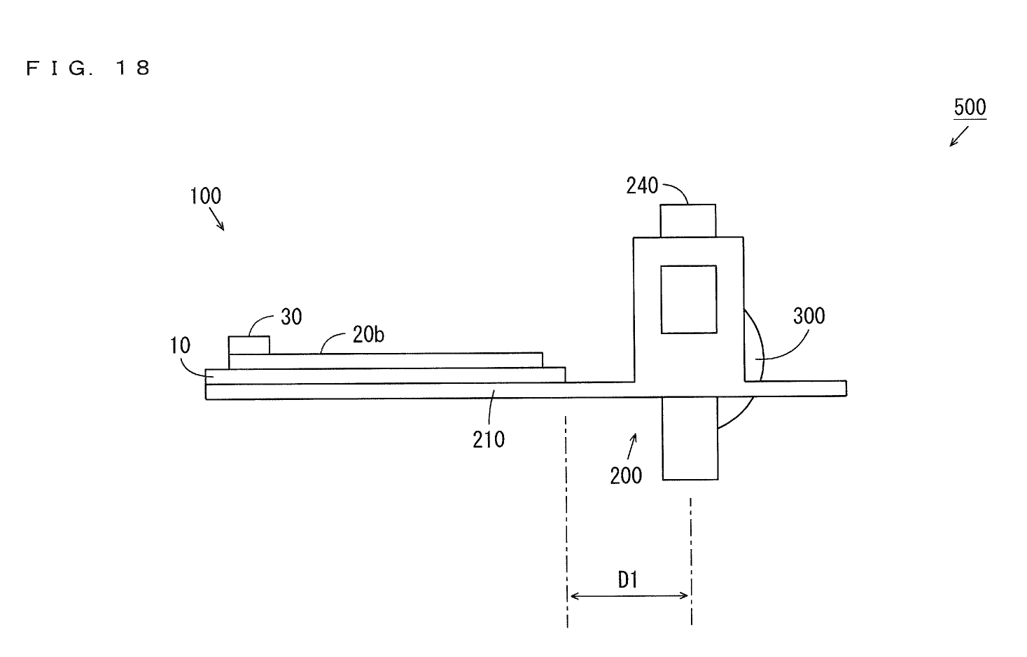

FIG. 14 is a schematic plan view showing the transmission operation of the antenna portion 100. In FIG. 14, the signal SG having a frequency (1 GHz, for example) in the gigahertz band is input to the semiconductor device 30. The semiconductor device 30 performs oscillation. Thus, the electromagnetic wave RW is transmitted from the tapered slot S of the antenna portion 100. The electromagnetic wave RW includes the digital intensity modulated signal wave having a frequency (0.3 THz, for example) in the terahertz band and a signal wave having a frequency (1 GHz, for example) in the gigahertz band.

### (4) Directivity of Antenna Portion

FIG. 15 is a schematic side view for explaining the directivity of the antenna portion 100. In FIG. 15, the antenna portion 100 radiates a carrier wave modulated by the signal wave as the electromagnetic wave RW. In this case, because the relative permittivity of the dielectric film 10 is low, the electromagnetic wave RW is not attracted to the dielectric film 10. Therefore, the electromagnetic wave RW advances in the central axis direction of the antenna portion 100.

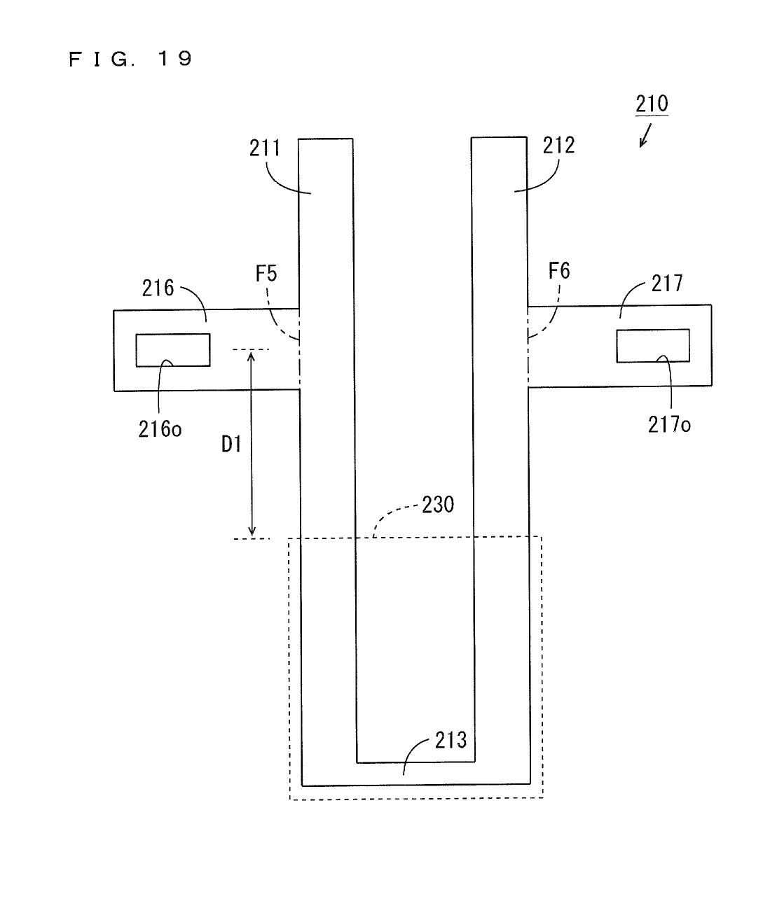

FIG. 16 is a schematic side view for explaining the change in directivity of the antenna portion 100. The dielectric film 10 of the antenna portion 100 and the support body 200 are flexible. Therefore, the antenna portion 100 and the insulating layer 220 can be bent along an axis that intersects with the central axis direction. Thus, as shown in FIG. 16, the radiation direction of the electromagnetic wave RW can be changed to any direction.

Further, the dielectric lens 300 is integrally supported by the support body 200. Therefore, in a case in which the antenna portion 100 and the support body 200 are bent in order to change the radiation direction of the electromagnetic wave RW, the position of the dielectric lens 300 is also changed while the light axis of the dielectric lens 300 is kept in the state of passing through the tapered slot S of the antenna portion 100. Thus, the electromagnetic wave RW in the terahertz band that is transmitted or received by the antenna portion 100 can be efficiently paralleled or converged.

### (5) Effects

In the method for manufacturing the antenna module 500 according to the present embodiment, the support layer 210 of the support body 200 is formed on the back surface of the dielectric film 10, and the dielectric lens 300 is provided on the support layer 210 with the insulating layer 220 sandwiched therebeteween. Thereafter, the support layer 210 is bent along the bent portions F1 to F4 such that the electromagnetic wave in the terahertz band that is transmitted or received by the electrodes 20a, 20b permeates through the dielectric lens 300.

In this case, it is possible to arrange the dielectric lens 300 at a position at which the light axis of the dielectric lens 300 passes through the tapered slot S of the antenna portion 100 by bending the support layer 210 without using a plurality of attachment members. Therefore, a manufacturing cost for the antenna module 500 is reduced, and the antenna module 500 can be easily assembled.

Further, in the antenna module 500 according to the present embodiment, the electromagnetic wave in the terahertz band is transmitted or received by the electrodes 20a, 20b formed on the main surface of the dielectric film 10. Further, the semiconductor device 30 mounted on the main surface of the dielectric film 10 performs detection and rectification, or oscillation. The electromagnetic wave transmitted or received by the electrodes 20a, 20b are converged or paralleled by permeating through the dielectric lens 300.

Further, because the dielectric film 10 is formed of resin, an effective relative permittivity of the surroundings of the electrodes 20a, 20b is low. Thus, the electromagnetic wave radiated from the electrodes 20a, 20b or received by the electrodes 20a, 20b is less likely attracted to the dielectric film 10. Therefore, the electromagnetic wave can be efficiently radiated, and better directivity of the antenna module 500 is obtained.

Here, the transmission loss α [dB/m] of the electromagnetic wave is expressed in the following formula by a conductor loss α1 and a dielectric loss α2.

α=α1+α2[dB/m]

Letting ∈_{ref} be an effective relative permittivity, f be a frequency, R(f) be conductor surface resistance and tan δ be a dielectric tangent, the conductor loss α1 and the dielectric loss α2 are expressed as below.

α1∝R(f)·√∈_{ref}[dB/m]

α2∝√∈_{ref}·tan δ·f[dB/m]

From the above expressions, if the effective relative permittivity ∈_{ref} is low, the transmission loss α of the electromagnetic wave is reduced.

In the antenna module 500 according to the present invention, because the effective relative permittivity of the surroundings of the electrodes 20a, 20b is low, the transmission loss of the electromagnetic wave is reduced. Thus, the transmission speed and the transmission distance can be improved. Further, the electromagnetic wave permeates through the dielectric lens 300, whereby the directivity and the antenna gain are improved.

### [2] Second Embodiment

### (1) Configuration of Antenna Module

Regarding the antenna module according to the second embodiment, difference from the antenna module 500 according to the first embodiment will be described. FIG. 17 is an external perspective view of the antenna module according to the second embodiment. FIG. 18 is a schematic side view of the antenna module of FIG. 17. As shown in FIGS. 17 and 18, the antenna module 500 includes the antenna portion 100, the support body 200 and the dielectric lens 300. The configuration of the antenna portion 100 in the present embodiment is similar to the configuration of the antenna portion 100 in the first embodiment. Details of the support body 200 and the dielectric lens 300 will be described below.

The support body 200 according to the present embodiment includes the support layer 210 and a lens holding member 240. The lens holding member 240 is formed of material having a shape-retaining property. In the present embodiment, the lens holding member 240 is formed of stainless. The lens holding member 240 may be formed of another metal such as aluminum or copper. Further, the lens holding member 240 may be formed of resin having a higher shape-retaining property than the dielectric film 10.

FIG. 19 is a schematic plan view of the support layer 210 of the support body 200 of FIG. 17. As shown in FIG. 19, the support layer 210 in the present embodiment includes projection plates 216, 217 instead of the reinforcement plates 214, 215 (FIG. 8) of the support layer 210 in the first embodiment.

The projection plate 216 is integrally formed at the support plate 211 to extend outward from the lateral side of the support plate 211. The projection plate 217 is integrally formed at the support plate 212 to extend outward from the lateral side of the support plate 212. Rectangular openings 216o, 217o are formed at the projection plates 216, 217. The distance between the center of each opening 216o, 217o in the longitudinal direction of the support layer 210 and the antenna portion arrangement region 230 is set to D1.

Bent portions F5, F6 are provided at the support layer 210 instead of the bent portions F1 to F4 (FIG. 8) of the support layer 210 in the first embodiment. In FIG. 19, the bent portions F5, F6 are indicated by the one-dot and dash line. The bent portion F5 is provided on the boundary line between the support plate 211 and the projection plate 216, and the bent portion F6 is provided on the boundary line between the support plate 212 and the projection plate 217.

The bent portions F5, F6 may be shallow line grooves, line marks or the like, for example. Alternatively, if the support layer 210 can be bent at the bent portions F5, F6, there may be nothing in particular at the bent portions F5, F6. In the present example, the bent portions F5, F6 are shallow line grooves provided at the main surface of the support layer 210.

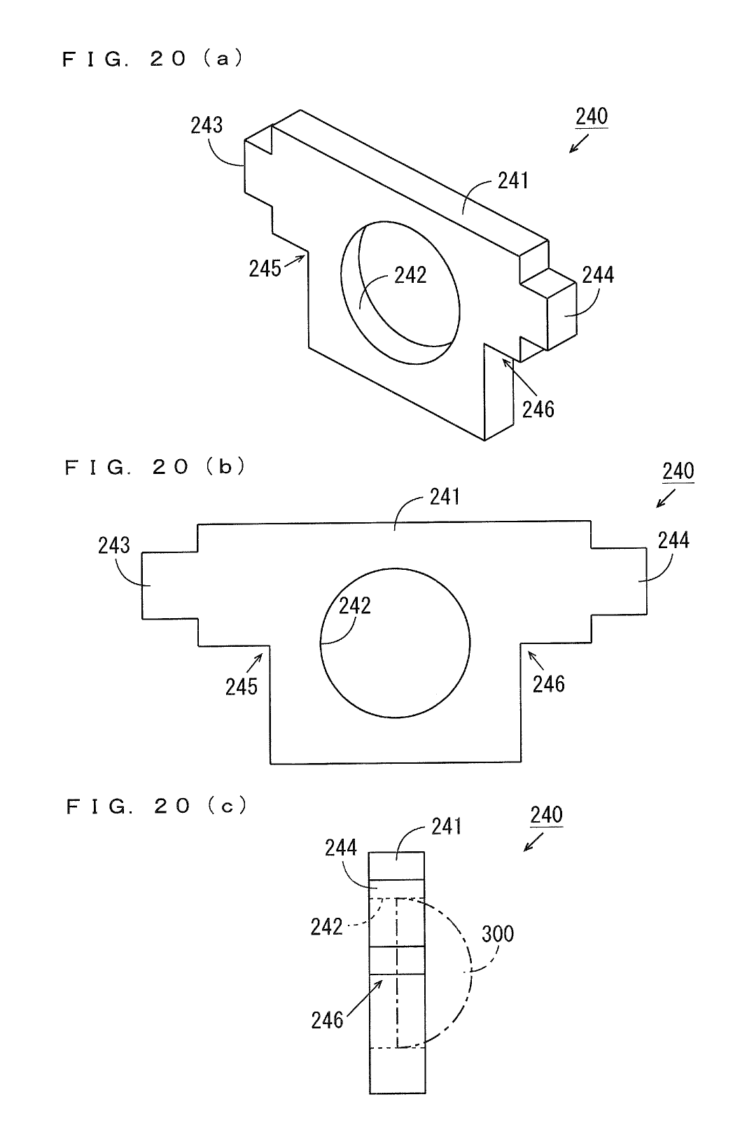

FIGS. 20(a) to 20(c) are diagrams showing the configuration of the lens holding member 240 of the support body 200 of FIG. 17. FIG. 20(a), 20(b), 20(c) respectively show a perspective view, a front view and a side view of the lens holding member 240.

As shown in FIGS. 20(a) to 20(c), the lens holding member 240 is formed of a plate-shaped member 241. A circular opening 242 is formed at the plate-shaped member 241. As shown in FIG. 20(c), the dielectric lens 300 can be fitted into the opening 242.

Projections 243, 244 are respectively formed to project outward in the vicinity of the upper ends of both of the side portions of the plate-shaped member 241. The projection 243 can be fitted into the opening 216o of the projection plate 216 of FIG. 19, and the projection 244 can be fitted into the opening 217o of the projection plate 217 of FIG. 19.

Cutouts 245, 246 are respectively formed at the lower ends of both of the side portions of the plate-shaped member 241. The lower surface of the cutout 245 can abut against the main surface of the support plate 211 of FIG. 19, and the lower surface of the cutout 246 can abut against the main surface of the support plate 212 of FIG. 19.

The dielectric lens 300 is fitted into the opening 242 of the lens holding member 240. In this case, the dielectric lens 300 can be reliably and easily supported by the lens holding member 240. In the present example, the dielectric lens 300 is a plane-convex lens, and formed of PTFE having a relative permittivity of 2.1. In the example of FIG. 20(c), a flat portion of the dielectric lens 300 that is a plane-convex lens is positioned at substantially half of the depth of the opening 242 of the lens holding member 240.

In this state, the lower surfaces of the cutouts 245, 246 of the lens holding member 240 are respectively arranged at the main surfaces of the support plates 211, 212 of the support layer 210. Thereafter, the support layer 210 is bent along the bent portions F5, F6 to form the valley fold. Thus, the projection 243 of the lens holding member 240 is fitted into the opening 216o of the projection plate 216, and the projection 244 is fitted into the opening 217o of the projection plate 217. In this case, as shown in FIG. 17, the lens holding member 240 is vertical to the main surface of the dielectric film 10.

In a state in which the lens holding member 240 is attached to the support layer 210, the opening 242 is formed such that the center of the dielectric lens 300 is positioned on the same plane as the main surface of the dielectric film 10. Thus, the dielectric lens 300 is held by the lens holding member 240 at a position spaced apart from the antenna portion 100 substantially by the distance D1 with the light axis passing through the tapered slot S of the antenna portion 100.

This configuration causes the electromagnetic wave in the terahertz band transmitted by the antenna portion 100 to be radiated through the opening 242 and the dielectric lens 300. In this case, the electromagnetic wave is paralleled by the dielectric lens 300. Further, the electromagnetic wave in the terahertz band is received by the antenna portion 100 through the opening 242 and the dielectric lens 300. In this case, the electromagnetic wave is converged by the dielectric lens 300. In this manner, the support layer 210 can reliably support the dielectric lens 300 without affecting the electromagnetic wave.

### (2) Method for Manufacturing Antenna Module

The method for manufacturing the antenna module 500 according to the present embodiment is similar to the method for manufacturing the antenna module 500 according to the first embodiment except for the following points.

In the process of FIG. 10(a), a plurality of shallow line grooves are formed at two predetermined positions at the main surface of the support layer 210. Thus, the bent portions F5, F6 of FIG. 19 are formed at the support layer 210. In the process of FIG. 10(b), the insulating layer 220 is not formed on the support layer 210.

In the process of FIG. 11(b), the projection plates 216, 217 are formed instead of the reinforcement plates 214, 215. Openings 216o, 217o are respectively formed at the projection plates 216, 217. The process of FIG. 12(b) is skipped.

Further, stainless is processed using a mold, whereby the lens holding member 240 is formed. Instead, a stainless member is mechanically processed, whereby the lens holding member 240 may be formed. Alternatively, wet-etching using a photoresist mask and a ferric chloride solution is performed on the stainless member, whereby the lens holding member 240 may be formed.

### (3) Effects

In the method for manufacturing the antenna module 500 according to the present embodiment, the support layer 210 of the support body 200 is formed on the back surface of the dielectric film 10, and the projection plates 216, 217 of the support layer 210 are bent along the bent portions F5, F6. Thereafter, the lens holding member 240 is supported by the bent projection plates 216, 217. The dielectric lens 300 is held by the lens holding member 240. The dielectric lens 300 can be arranged at a position at which the light axis of the dielectric lens 300 passes through the tapered slot S of the antenna portion 100. Therefore, a manufacturing cost for the antenna module 500 is reduced, and the antenna module 500 can be easily assembled.

Further, in the antenna module 500 according to the present embodiment, the electromagnetic wave in the terahertz band is transmitted or received by the electrodes 20a, 20b formed on the main surface of the dielectric film 10. Further, the semiconductor device 30 mounted on the main surface of the dielectric film 10 performs detection and rectification, or oscillation. The electromagnetic wave transmitted or received by the electrodes 20a, 20b is converged or paralleled by permeating through the dielectric lens 300.

Further, because the dielectric film 10 is formed of resin, the effective relative permittivity of the surroundings of the electrodes 20a, 20b is reduced. Thus, the electromagnetic wave radiated from the electrodes 20a, 20b or the electromagnetic wave received by the electrodes 20a, 20b is less likely attracted to the dielectric film 10. Therefore, the electromagnetic wave can be efficiently radiated, and the better directivity of the antenna module 500 is obtained. Further, because the effective relative permittivity of the surroundings of the electrodes 20a, 20b is low, the transmission loss of the electromagnetic wave is reduced. Thus, the transmission speed and the transmission distance can be improved. Further, the electromagnetic wave permeates through the dielectric lens 300, so that the directivity and the antenna gain are improved.

### [3] Other Embodiments

(1) While the dielectric lens 300 that is a plane-convex lens is formed on the one surface of the insulating layer 220 in the antenna module 500 according to the first embodiment, the invention is not limited to this. The one plane-convex lens is formed on the one surface of the insulating layer 220, and another plane-convex lens may be formed on another surface of the insulating layer 220. In this case, the dielectric lens 300 that is a double-convex lens is constituted by the two plane convex lenses.

Similarly, while the dielectric lens 300, that is a plane-convex lens, is fitted into the opening 242 from the one surface side of the lens holding member 240 in the antenna module 500 according to the second embodiment, the invention is not limited to this. The one plane-convex lens is fitted into the opening 242 from the one surface of the lens holding member 240, and another plane-convex lens may be fitted into the opening 242 from another surface of the lens holding member 240. In this case, the dielectric lens 300 that is double-convex lens is constituted by the two plane-convex lens.

Alternatively, in the antenna module 500 according to the second embodiment, the dielectric lens 300, that is a double-convex lens, may be fitted into the opening 242 of the lens holding member 240 instead of the plane-convex lens.

(2) While the three reinforcement plates 213 to 215 are provided at the support layer 210 in the antenna module 500 according to the first embodiment, the invention is not limited to this. In a case in which the strength of the support layer 210 is sufficiently high, two or less reinforcement plates may be provided at the support layer 210. On the other hand, in a case in which the strength of the support layer 210 is further increased, four or more reinforcement plates may be provided at the support layer 210.

Similarly, while the one reinforcement plate 213 is provided at the support layer 210 in the antenna module 500 according to the second embodiment, the invention is not limited to this. In a case in which the strength of the support layer 210 is sufficiently high, the reinforcement plate 213 does not have to be provided at the support layer 210. On the other hand, in a case in which the strength of the support layer 210 is further increased, two or more reinforcement plates may be provided at the support layer 210.

(3) While the electrodes 20a, 20b and the semiconductor device 30 are provided at the main surface of the dielectric film 10 in the above-mentioned embodiment, the invention is not limited to this. The electrodes 20a, 20b and the semiconductor device 30 may be provided at the back surface of the dielectric film 10. Alternatively, the electrodes 20a, 20b may be provided at one of the main surface and the back surface of the dielectric film 10, and the semiconductor device 30 may be provided at the other one of the main surface and the back surface of the dielectric film 10.

(4) The order of the process of FIG. 11(b), the process of FIG. 12(a) and the process of FIG. 12(b) is not limited to the order described in the first embodiment. For example, the process of the FIG. 12(a) may be performed before the process of FIG. 11(b), the process of FIG. 12(b) may be performed before the process of FIG. 11(b) and the process of FIG. 12(a), and the process of FIG. 12(a) may be performed after the process of FIG. 11(b) and the process of FIG. 12(b).

### [4] Inventive Example

### (1) Dimensions of Antenna Module

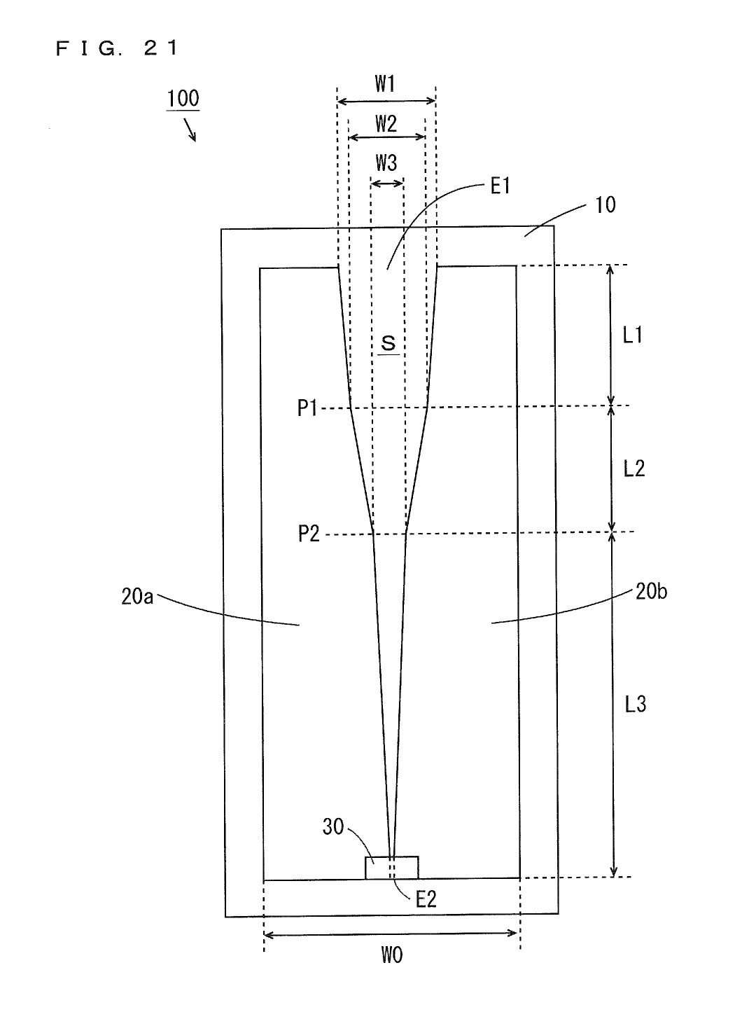

Each type of characteristics of the antenna module according to the above-mentioned embodiment were evaluated by the electromagnetic field simulation. FIG. 21 is a schematic plan view for explaining the dimensions of the antenna portion 100 of the antenna module used in the electromagnetic field simulation. The distance W0 between the outer end edges of the electrodes 20a, 20b in the width direction is 2.83 mm. The width W1 of the tapered slot S at the opening end E1 is 1.11 mm.

The widths W2, W3 of the tapered slot S at positions P1, P2 between the opening end E1 and the mount end E2 are 0.88 mm and 0.36 mm, respectively. The length L1 between the opening end E1 and the position P1 is 1.49 mm, and the length L2 between the position P1 and the position P2 is 1.49 mm. The length L3 between the position P2 and the mount end E2 is 3.73 mm. The width of the tapered slot S at the mount end E2 is 50 μm.

Various types of the electromagnetic field simulation regarding the antenna module having the antenna portion 100 of FIG. 21 were performed as the inventive example and the comparative example.

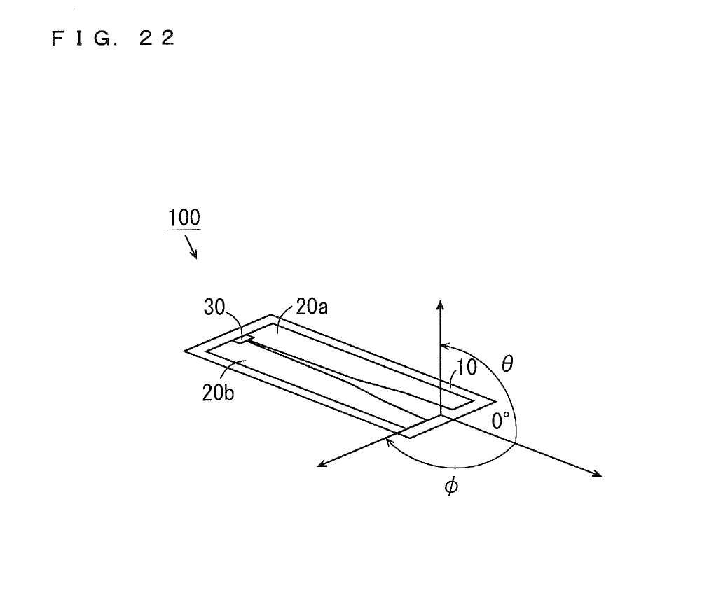

FIG. 22 is a schematic diagram for explaining the definition of the reception angle of the antenna portion 100 in the simulation. In FIG. 22, the central axis direction of the antenna portion 100 is considered as 0°. Further, a plane parallel to the main surface of the dielectric film 10 is referred to as a parallel plane, and a plane vertical to the main surface of the dielectric film 10 is referred to as a vertical plane. An angle formed with respect to the central axis direction in the parallel plane is referred to as an azimuth angle φ, and an angle formed with respect to the central axis direction in the vertical plane is referred to as an elevation angle θ.

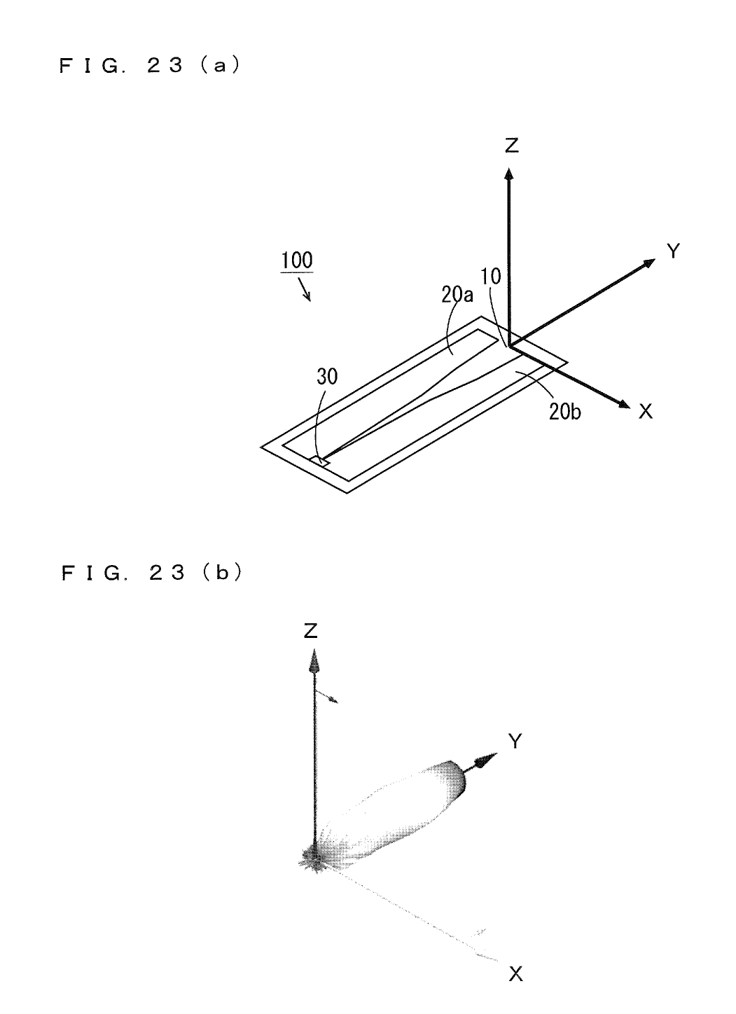

FIGS. 23(a) and 23(b) are diagrams showing the results of the three-dimensional electromagnetic field simulation of the antenna module. FIG. 23(a) is a diagram for explaining the definition of the directions of the antenna portion 100, and FIG. 23(b) is a diagram indicating the radiation characteristics (directivity) of the antenna portion 100.

As shown in FIG. 23(a), the central axis direction of the antenna portion 100 is referred to as the Y direction, a direction parallel to the main surface of the dielectric film 10 and orthogonal to the Y direction is referred to as the X direction, and a direction vertical to the main surface of the dielectric film 10 is referred to as the Z direction. As shown in FIG. 23(b), the electromagnetic wave is radiated in the Y direction by the antenna portion 100.

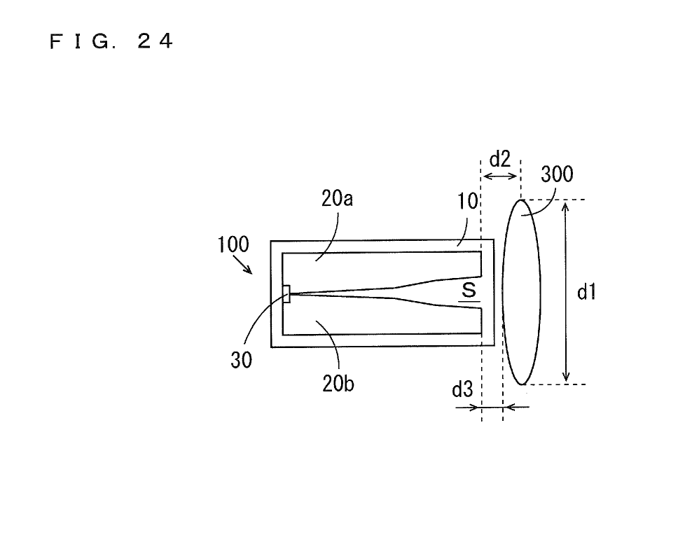

FIG. 24 is a plan view showing the configuration of the antenna module according to the inventive example. As shown in FIG. 24, the antenna module according to the inventive example includes the antenna portion 100 and the dielectric lens 300 of FIG. 21. The dielectric lens 300 is a double-convex lens, and is formed of PTFE having the relative permittivity of 2.1.

The diameter of the dielectric lens 300 is d1. The distance from the opening end E1 (FIG. 21) of the antenna portion 100 to the centeral position in the thickness direction of the dielectric lens 300 is d2. The distance from the opening end E1 of the antenna portion 100 to the front surface of the dielectric lens 300 is d3.

### (2) Difference in Characteristics due to Presence/Absence of Dielectric Lens

First, difference in characteristics of the antenna module due to the presence/absence of the dielectric lens 300 was considered by the electromagnetic field simulation.

In the antenna module according to the inventive example 1, a diameter d1, a distance d2 and a distance d3 were respectively set to 4.9 mm, 1.9 mm and 0.6 mm. In the antenna module according to the inventive example 2, the diameter d1, the distance d2 and the distance d3 were respectively set to 5.4 mm, 1.7 mm and 0.9 mm. In the antenna module according to the inventive example 3, the diameter d1, the distance d2 and the distance d3 were respectively set to 7.7 mm, 2.7 mm and 0.9 mm. The antenna module according to the comparative example 1 does not have the dielectric lens 300.

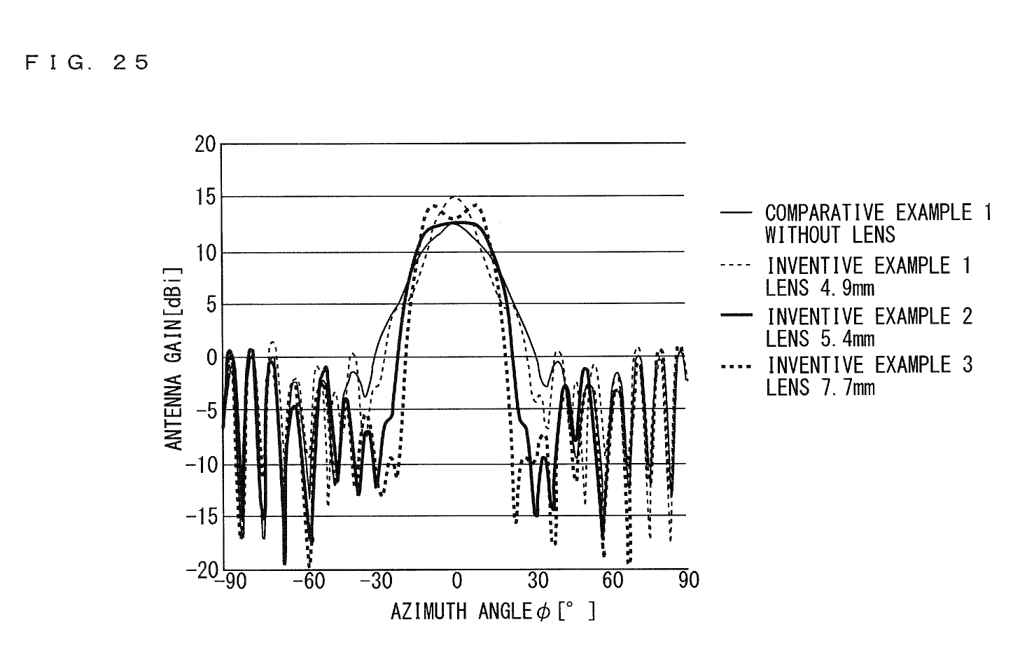

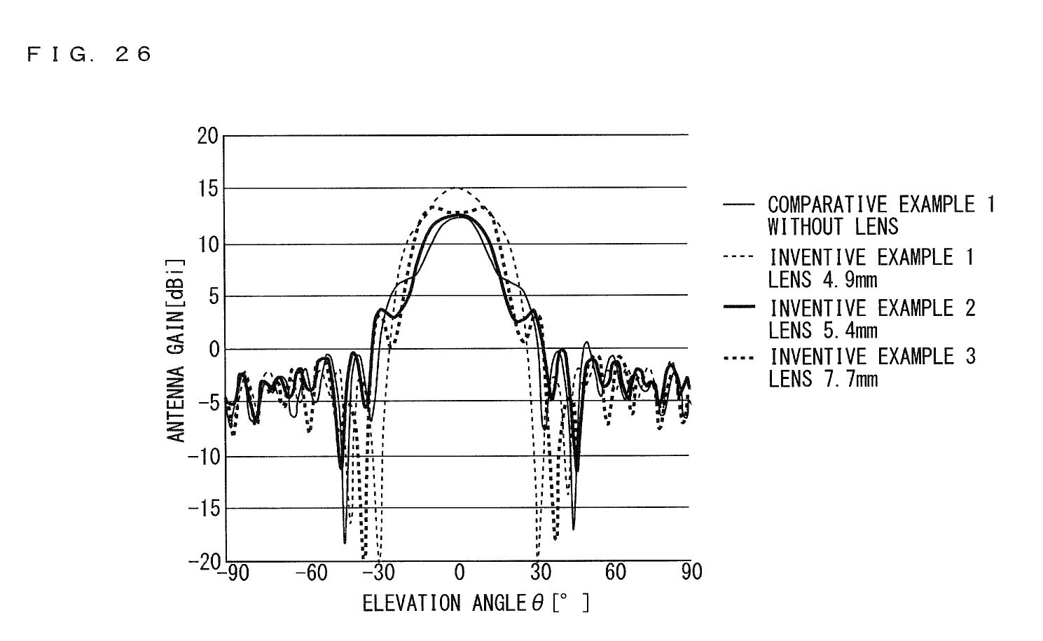

The antenna gain of the antenna module according to the inventive examples 1 to 3 and the comparative example 1 were found by the electromagnetic field simulation. FIGS. 25 and 26 are diagrams showing the simulation results of the antenna gain of the antenna module according to the inventive examples 1 to 3 and the comparative example 1. The ordinate of FIG. 25 indicates the antenna gain [dBi], and the abscissa indicates the azimuth angle φ. The ordinate of FIG. 26 indicates the antenna gain [dBi], and the abscissa indicates the elevation angle θ.

In FIGS. 25 and 26, the antenna gain of the antenna module according to the inventive example 1 is indicated by the thin dotted line. The antenna gain of the antenna module according to the inventive example 2 is indicated by the thick solid line. The antenna gain of the antenna module according to the inventive example 3 is indicated by the thick dotted line. The antenna gain of the antenna module according to the comparative example 1 is indicated by the thin solid line. The maximum antenna gain of the antenna portion 100 in the inventive examples 1 to 3 and the comparative example 1 shown in FIGS. 25 and 26 are shown in Table 1.

TABLE 1

| | MAXIMUM ANTENNA GAIN |
|---|---|
| INVENTIVE EXAMPLE 1 | 15.03 [dBi] |
| INVENTIVE EXAMPLE 2 | 12.53 [dBi] |
| INVENTIVE EXAMPLE 3 | 14.28 [dBi] |
| COMPARATIVE EXAMPLE 1 | 12.42 [dBi] |

As shown in Table 1, the maximum antenna gain of the antenna module according to the inventive examples 1 to 3 were respectively 15.03 dBi, 12.53 dBi and 14.28 dBi. On the other hand, the maximum antenna gain of the antenna module according to the comparative example 1 was 12.42 dBi.

From the results of the inventive examples 1 to 3 and the comparative example 1, it was confirmed that the maximum antenna gain is improved when the dielectric lens 300 is provided at the antenna module. In particular, the maximum antenna gain is significantly improved in the inventive examples 1, 3. This is considered to be because the electromagnetic wave is converged by the dielectric lens 300.

Further, as shown in FIG. 25, the antenna gain is kept substantially constant in a range in which the azimuth angle φ of not less than −10° and not more than +10° in the inventive example 2. Similarly, as shown in FIG. 26, the elevation angle θ is kept substantially constant in a range in which the elevation angle φ of not less than −10° and not more than +10° in the inventive example 2. Thus, it was confirmed that the electromagnetic wave is substantially paralleled by the dielectric lens 300.

Thus, it was confirmed that the maximum antenna gain can be improved, or the electromagnetic wave can be paralleled by the appropriate selection of the diameter of the dielectric lens 300 provided at the antenna module.

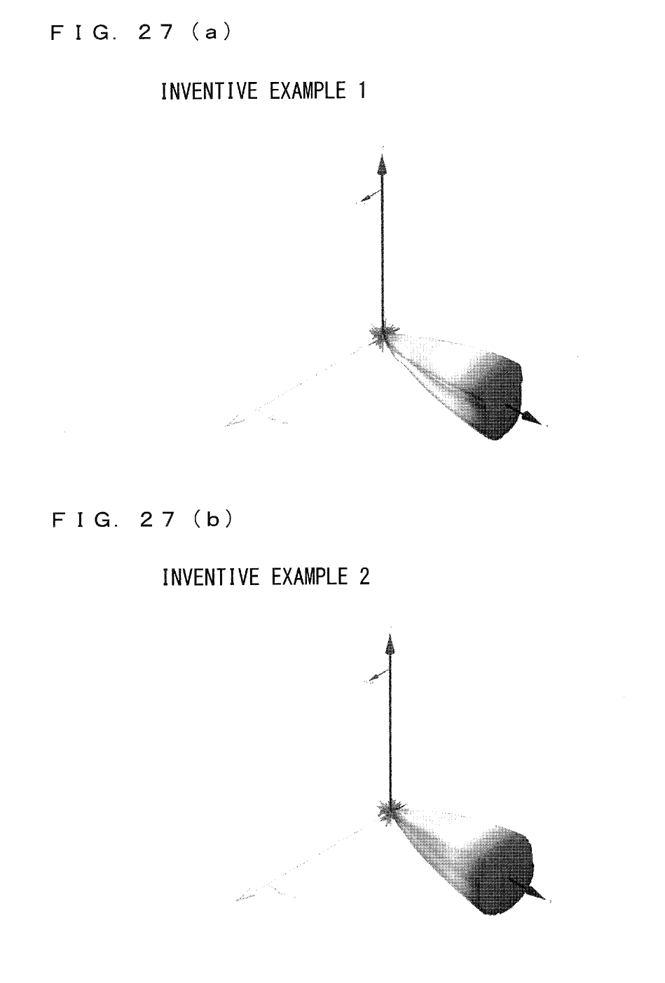

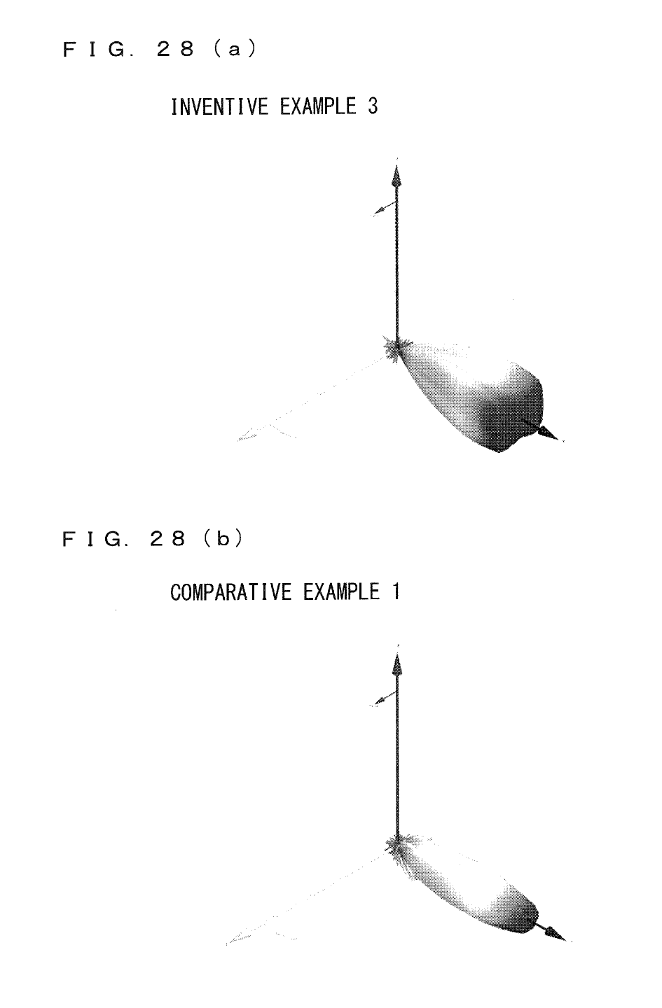

FIGS. 27(a), 27(b), 28(a) and 28(b) are diagrams showing the results of the three-dimensional electromagnetic field simulation of the antenna module according to the inventive examples 1 to 3 and the comparative example 1. FIGS. 27(a), 27(b), 28(a) and 28(b) respectively show the radiation characteristics (directivity) in the antenna module according to the inventive examples 1 to 3 and the comparative example 1.

As shown in FIGS. 27(a), 27(b), 28(a) and 28(b), it was confirmed that a region having the higher antenna gain (a region having a higher concentration) in the inventive examples 1 to 3 is further enlarged than a region having the higher antenna gain in the comparative example 1. Therefore, an allowable range of a positional shift of the receiver that receives the electromagnetic wave transmitted from the antenna module can be increased by the appropriate selection of the diameter of the dielectric lens 300. Further, this enables the electromagnetic wave to reach even farther.

### (3) Difference in Characteristics due to Presence/Absence of Support Body in First Embodiment

Next, difference in characteristics due to the presence/absence of the support body 200 in the first embodiment was considered.

In the antenna module according to the inventive examples 4, 5, the diameter d1, the distance d2 and the distance d3 were respectively set to 5.4 mm, 1.7 mm and 0.9 mm. Further, the antenna module according to the inventive example 5 has the support body 200 (hereinafter referred to as a support body 200A) in the first embodiment. On the other hand, the antenna module according to the inventive example 4 does not have the support body 200A. The antenna module according to the comparative example 2 does not have the support body 200A or the dielectric lens 300.

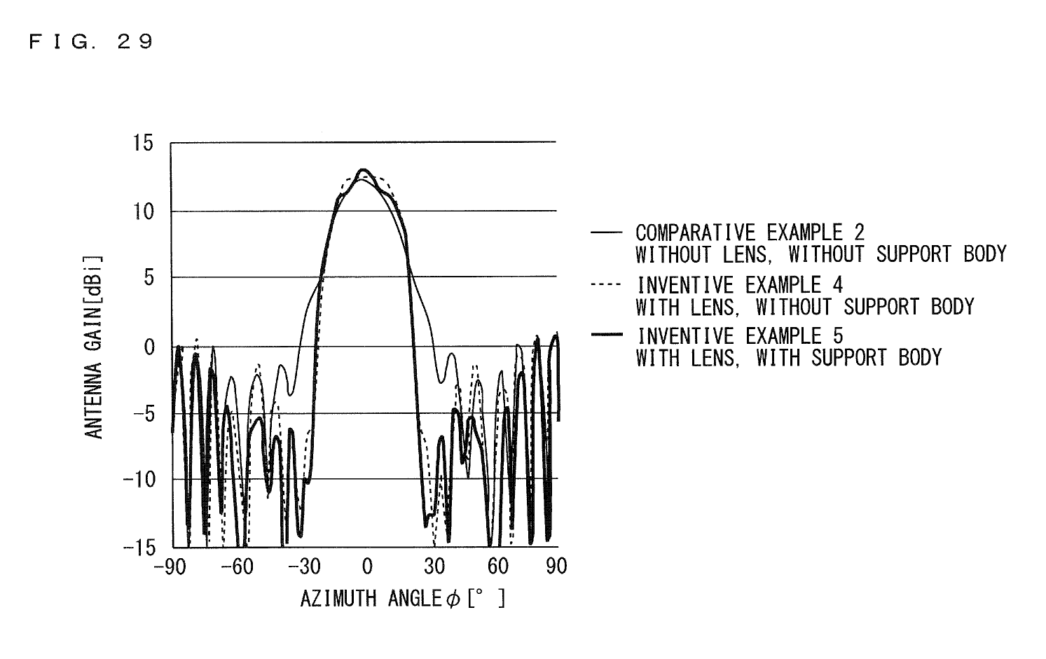

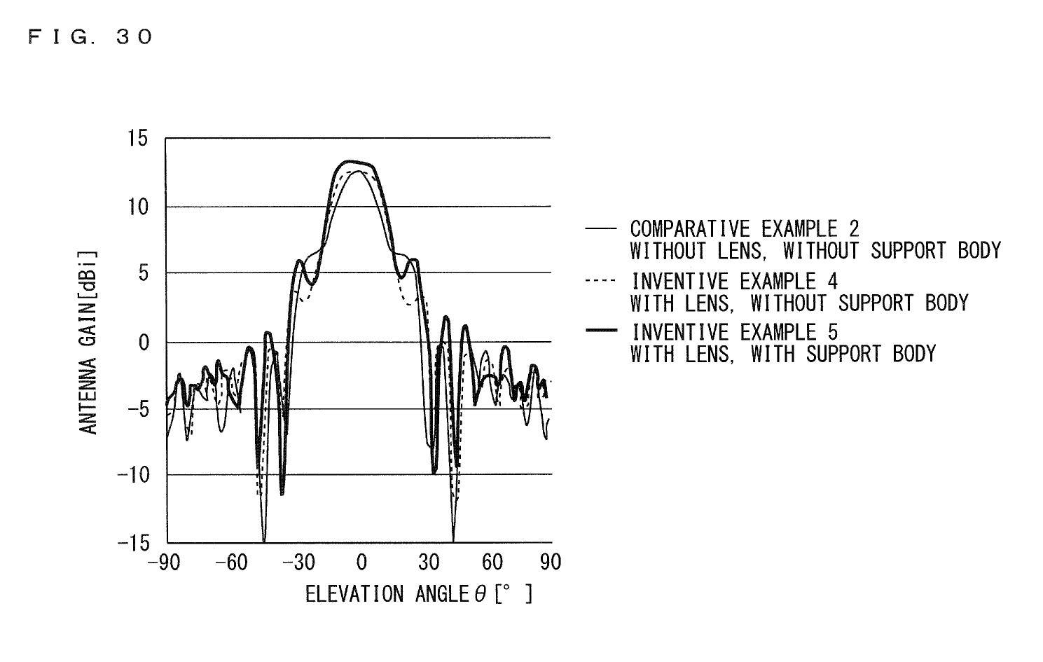

The antenna gain of the antenna module according to the inventive examples 4, 5 and the comparative example 2 was found by the electromagnetic field simulation. FIGS. 29 and 30 are diagrams showing the simulation results of the antenna gain of the antenna module according to the inventive examples 4, 5 and the comparative example 2. The ordinate of FIG. 29 indicates the antenna gain [dBi], and the abscissa indicates the azimuth angle φ. The ordinate of FIG. 30 indicates the antenna gain [dBi], and the abscissa indicates the elevation angle θ.

In FIGS. 29 and 30, the antenna gain of the antenna module according to the inventive example 4 is indicated by the thin dotted line. The antenna gain of the antenna module according to the inventive example 5 is indicated by the thick solid line. The antenna gain of the antenna module according to the comparative example 2 is indicated by the thin solid line. The maximum antenna gain of the antenna module according to the inventive examples 4, 5 and the comparative example 2 shown in FIGS. 29 and 30 are shown in Table 2.

TABLE 2

| | MAXIMUM ANTENNA GAIN |
|---|---|
| INVENTIVE EXAMPLE 4 | 12.50 [dBi] |
| INVENTIVE EXAMPLE 5 | 13.08 [dBi] |
| COMPARATIVE EXAMPLE 2 | 12.42 [dBi] |

As shown in Table 2, the maximum antenna gain of the antenna module according to the inventive examples 4, 5 were respectively 12.50 dBi and 13.08 dBi. On the other hand, the maximum antenna gain of the antenna module according to the comparative example 2 was 12.42 dBi.

Similarly to the results of the inventive examples 1 to 3 and the comparative example 1, from the results of the inventive examples 4, 5 and the comparative example 2, it was confirmed that the maximum antenna gain of the antenna module is improved because the dielectric lens 300 is provided at the antenna module. From the results of the inventive examples 4, 5, it was confirmed that the maximum antenna gain of the antenna module is further improved because the support body 200A is provided at the antenna module. This is considered to be because the support body 200A made of stainless reduces the radiation of the electromagnetic wave to the sides of the tapered slot S of the antenna portion 100. As a result, the antenna gain obtained when the azimuth angle φ and the elevation angle θ are around 0° is improved.

Further, as shown in FIGS. 29 and 30, in the antenna module according to the inventive examples 4, 5, better directivity as compared to the antenna module according to the comparative example 2 is obtained.

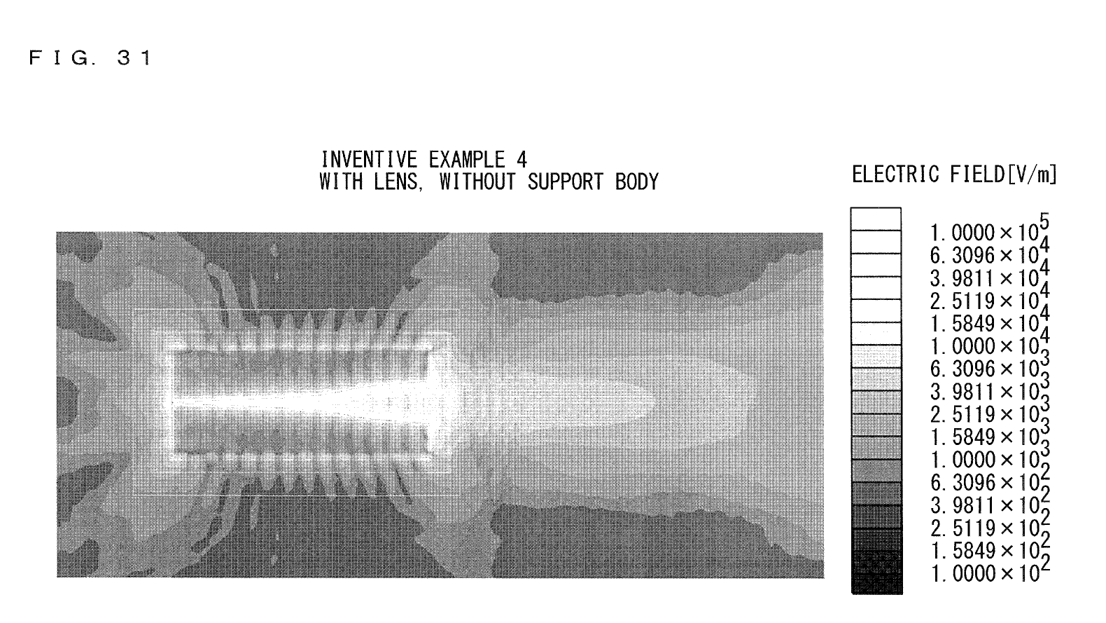

FIGS. 31 to 34 are diagrams respectively showing the simulation results of the electric field distribution of the electromagnetic wave radiated by the antenna module according to the inventive examples 4, 5 and the comparative examples 3,4. The antenna module according to the comparative example 3 does not have the dielectric lens 300, but has the support body 200A. The antenna module according to the comparative example 4 does not have the dielectric lens 300 or the support body 200A.

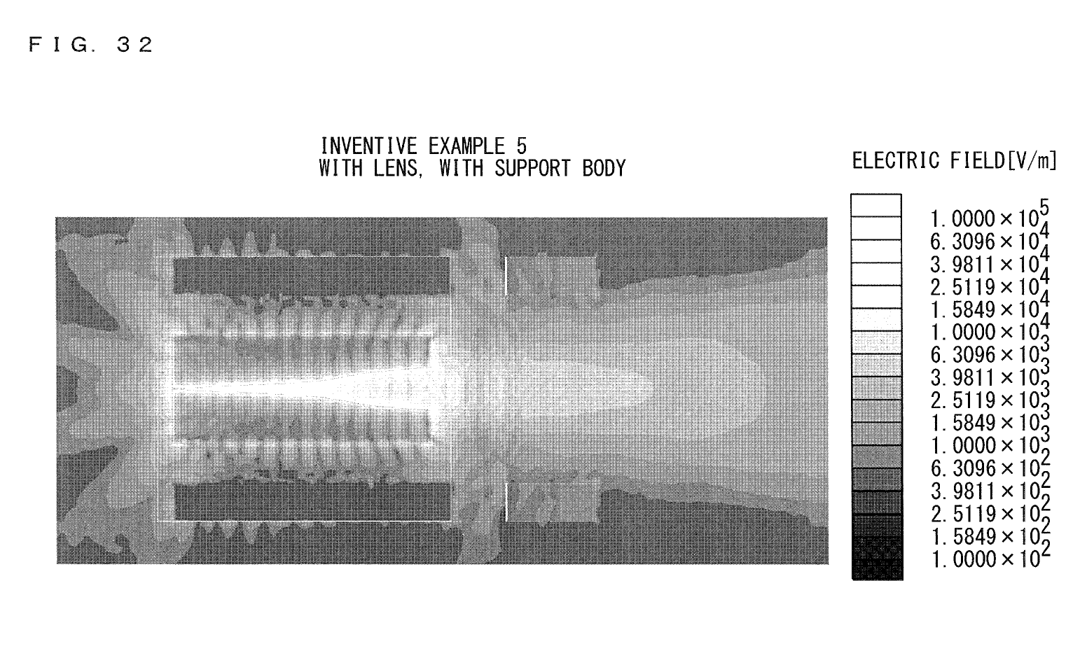

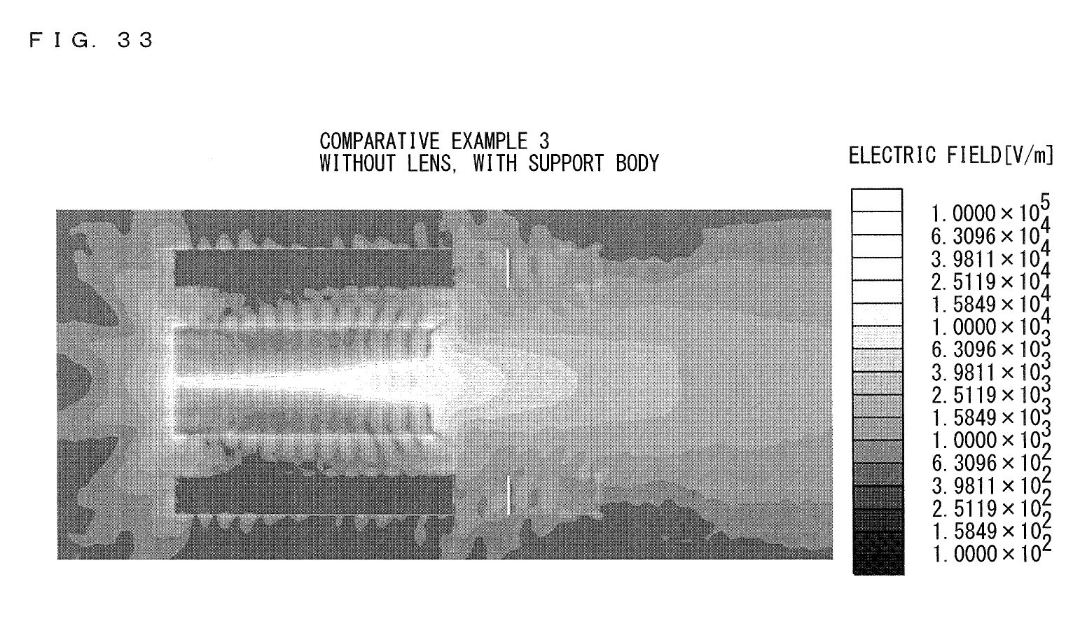

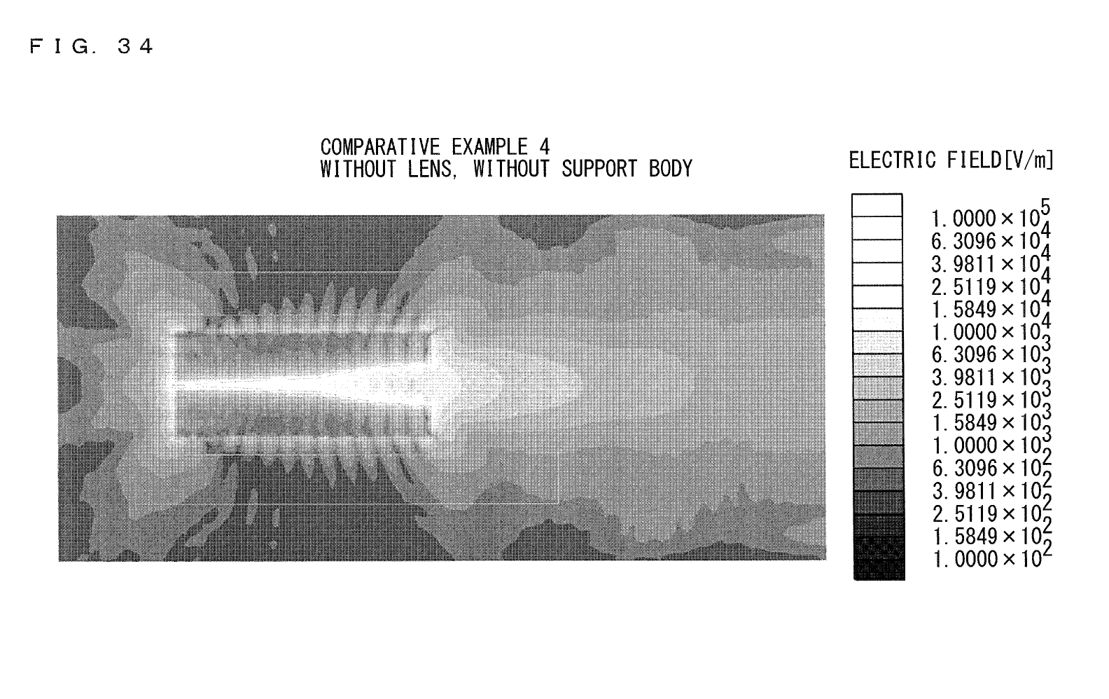

From the comparison between the inventive example 4 of FIG. 31 and the inventive example 5 of FIG. 32, and the comparison between the comparative example 3 of FIG. 33 and the comparative example 4 of FIG. 34, it was confirmed that the spread of the electromagnetic wave radiated from the antenna module is suppressed by the support body 200A. Further, from the comparison between the inventive example 4 of FIG. 31 and the comparative example 4 of FIG. 34, and the comparison between the inventive example 5 of FIG. 32 and the comparative example 3 of FIG. 33, it was confirmed that the spread of the electromagnetic wave radiated from the antenna module is suppressed by the dielectric lens 300.

### (4) Difference in Characteristics due to Presence/Absence of Support Body in Second Embodiment

Next, the difference in characteristics due to the presence/absence of the support body 200 in the second embodiment was considered by the electromagnetic field simulation.

In the antenna module according to the inventive examples 6 and 7, the diameter d1, the distance d2 and the distance d3 were respectively set to 4.9 mm, 1.9 mm and 0.6 mm. Further, the antenna module according to the inventive example 7 has the support body 200 (hereinafter referred to as a support body 200B) of FIG. 17 in the second embodiment. On the other hand, the antenna module according to the inventive example 6 does not have the support body 200B. The antenna module according to the comparative example 5 does not have the support body 200B or the dielectric lens 300.

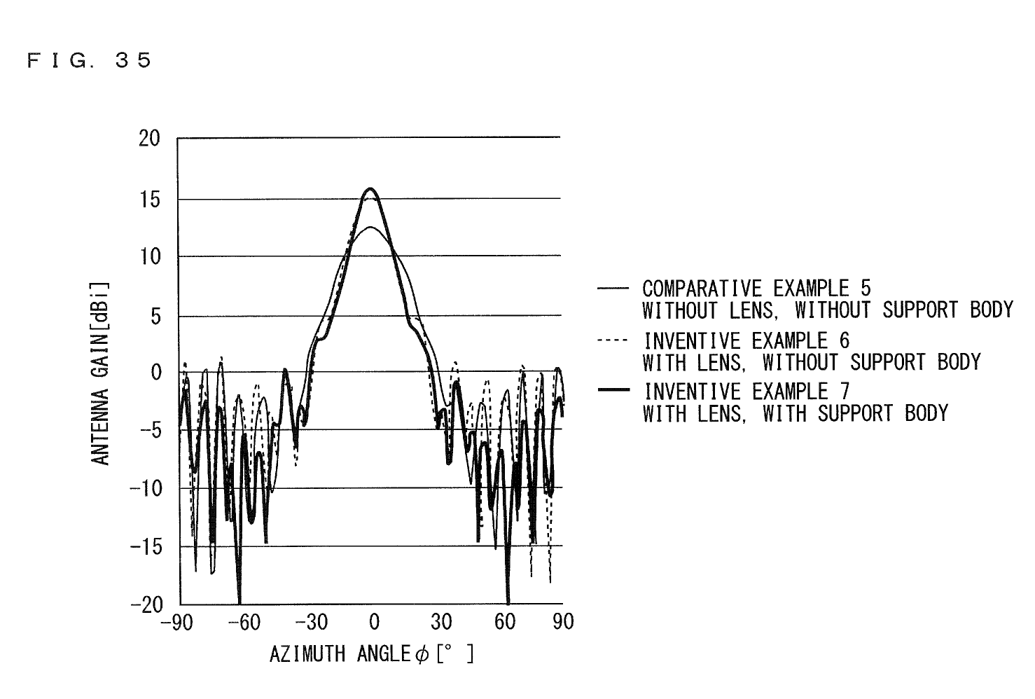

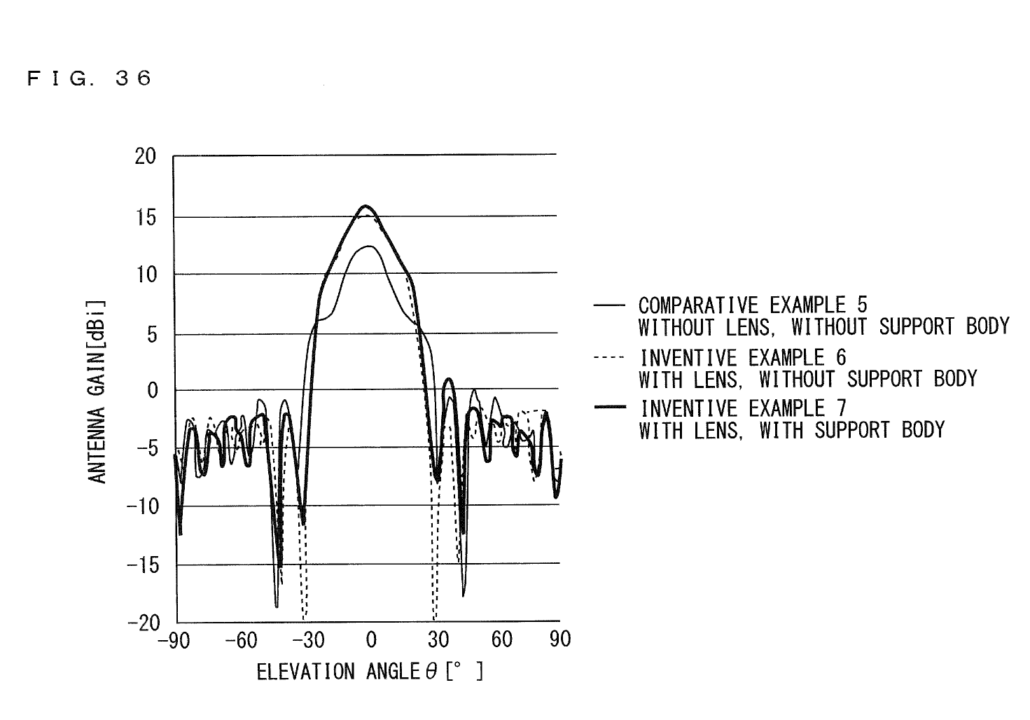

The antenna gain of the antenna module according to the inventive examples 6, 7 and the comparative example 5 was found by the electromagnetic field simulation. FIGS. 35 and 36 are diagrams showing the results of the electromagnetic field simulation of the antenna gain of the antenna module according to the inventive examples 6, 7 and the comparative example 5. The ordinate of FIG. 35 indicates the antenna gain [dBi], and the abscissa indicates the azimuth angle φ. The ordinate of FIG. 36 indicates the antenna gain [dBi], and the abscissa indicates the elevation angle θ.

In FIGS. 35 and 36, the antenna gain of the antenna module according to the inventive example 6 is indicated by the thin dotted line. The antenna gain of the antenna module according to the inventive example 7 is indicated by the thick solid line. The antenna gain of the antenna module according to the comparative example 5 is indicated by the thin solid line. The maximum antenna gain of the antenna module according to the inventive examples 6, 7 and the comparative example 5 shown in FIGS. 35 and 36 are shown in Table 3.

TABLE 3

| | MAXIMUM ANTENNA GAIN |
|---|---|
| INVENTIVE EXAMPLE 6 | 15.03 [dBi] |
| INVENTIVE EXAMPLE 7 | 15.75 [dBi] |
| COMPARATIVE EXAMPLE 5 | 12.42 [dBi] |

As shown in Table 3, the maximum antenna gain of the antenna module according to the inventive examples 6, 7 were respectively 15.03 dBi and 15.75 dBi. On the other hand, the maximum antenna gain of the antenna module according to the comparative example 5 was 12.42 dBi.

Similarly to the results of the inventive examples 1 to 5 and the comparative example 1, 2, from the results of the inventive examples 6, 7 and the comparative example 5, it was confirmed that the maximum antenna gain of the antenna module was improved because the dielectric lens 300 is provided at the antenna module. From the results of the inventive examples 6,7, it was confirmed that the maximum antenna gain of the antenna module is further improved because the support body 200B is provided at the antenna module. This is considered to be because the support body 200B made of stainless reduces the radiation of the electromagnetic wave to the sides of the tapered slot S of the antenna portion 100. As a result, the antenna gain obtained when the azimuth angle φ and the elevation angle θ are around 0° is improved.

Further, as shown in FIGS. 35 and 36, in the antenna module according to the inventive examples 6, 7, better directivity as compared to the antenna module according to the comparative example 5 is obtained.

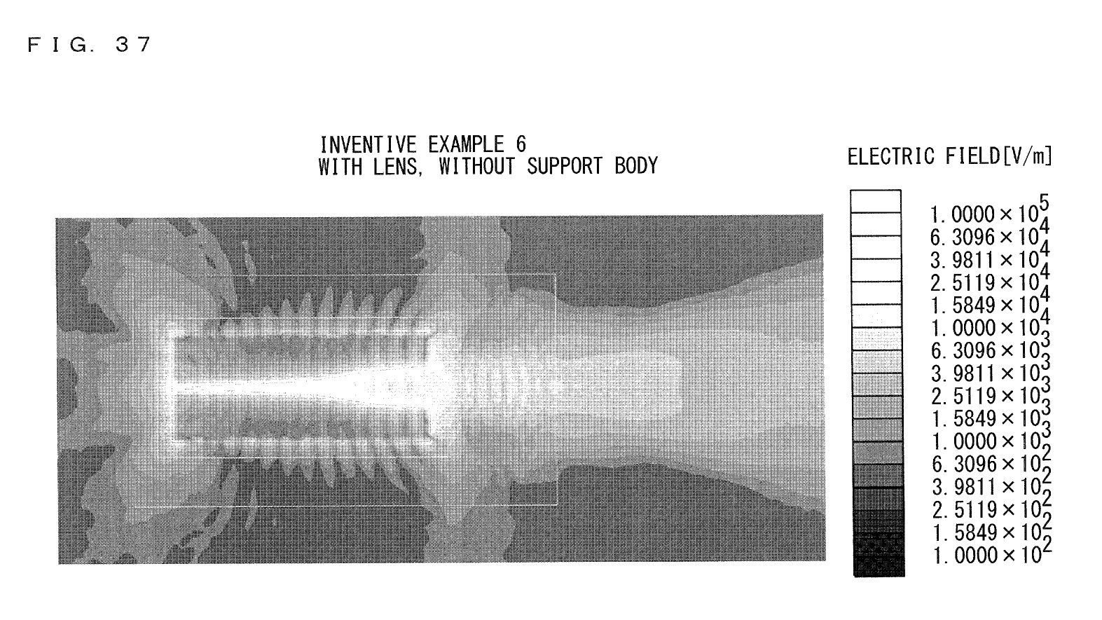

FIGS. 37 to 39 are diagrams respectively showing the simulation results of the electric field distribution of the electromagnetic wave radiated by the antenna module according to the inventive example 6, 7 and the comparative example 6. The antenna module according to the comparative example 6 does not have the dielectric lens 300 but has the support body 200B. Further, the simulation results of the electric field distribution of the electromagnetic wave radiated by the antenna module that does not have the dielectric lens 300 or the support body 200B are similar to the simulation results of the electric field distribution of the electromagnetic wave radiated by the antenna module according to the comparative example 4 of FIG. 34.

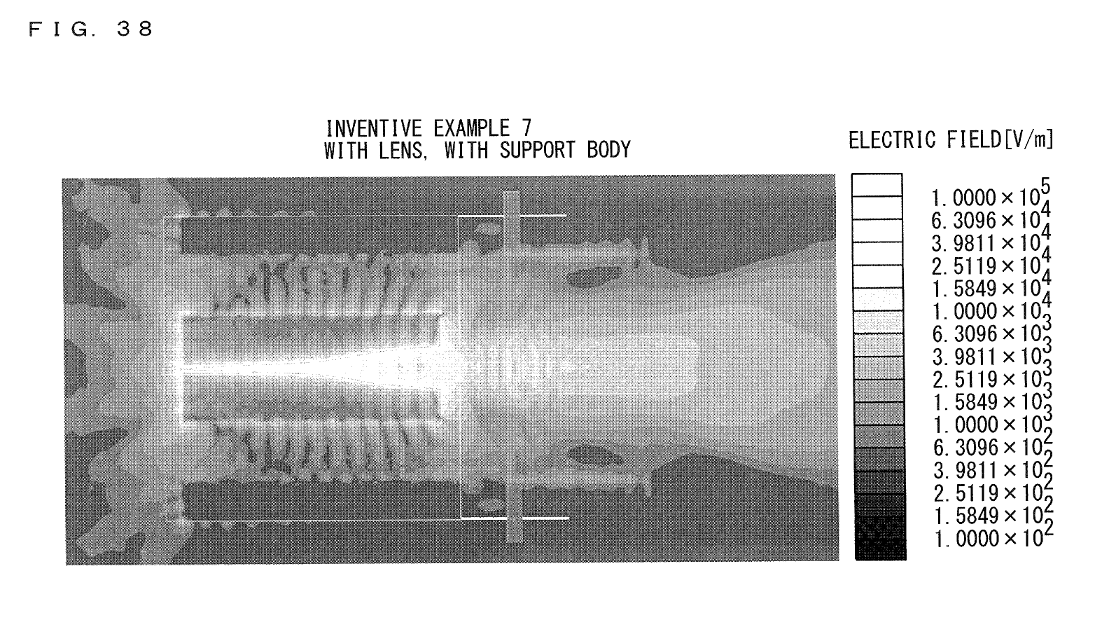

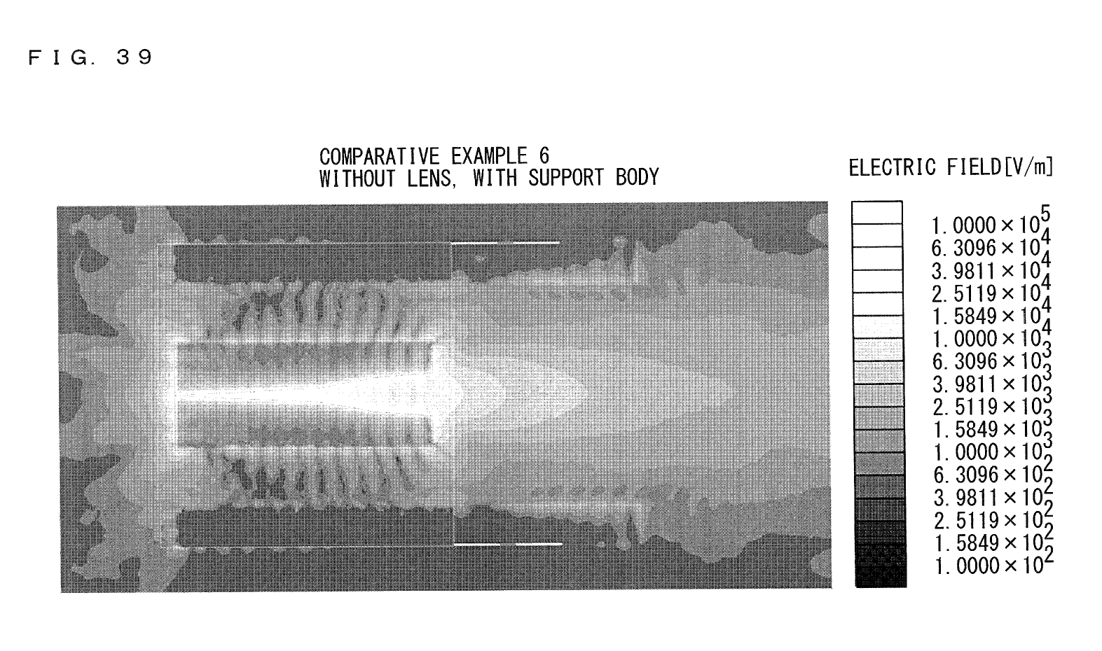

From the comparison between the inventive example 6 of FIG. 37 and the inventive example 7 of FIG. 38, and the comparison between the comparative example 6 of FIG. 39 and the comparative example 4 of FIG. 34, it was confirmed that the spread of the electromagnetic wave radiated from the antenna module is suppressed by the support body 200B. Further, from the comparison between the inventive example 6 of FIG. 37 and the comparative example 4 of FIG. 34, and the comparison between the inventive example 7 of FIG. 38 and the comparative example 6 of FIG. 39, it was confirmed that the spread of the electromagnetic wave radiated from the antenna module is suppressed by the dielectric lens 300.

### (5) Difference in Characteristics due to Number of Dielectric Lens

In the antenna module according to the inventive examples 8,9, the diameter d1, the distance d2 and the distance d3 were respectively set to 5.4 mm, 1.7 mm and 0.9 mm. Further, the antenna module according to the inventive example 9 has yet another dielectric lens 300 having the diameter of 5.4 mm at a position that is spaced apart from the dielectric lens 300 of FIG. 24 by 7 mm, and does not have the support body 200A. On the other hand, the antenna module according to the inventive example 8 does not have another dielectric lens 300 or the support body 200A.

In the antenna module according to the inventive example 10, the diameter d1, the distance d2 and the distance d3 was respectively set to 4.9 mm, 1.9 mm and 0.6 mm. Further, the antenna module according to the inventive example 10 has yet another dielectric lens 300 having the diameter of 5.4 mm at a position that is spaced apart from the dielectric lens 300 of FIG. 24 by 7 mm, and has the support body 200A. The antenna module according to the comparative example 7 does not have the dielectric lens 300, another dielectric lens 300 or the support body 200A.

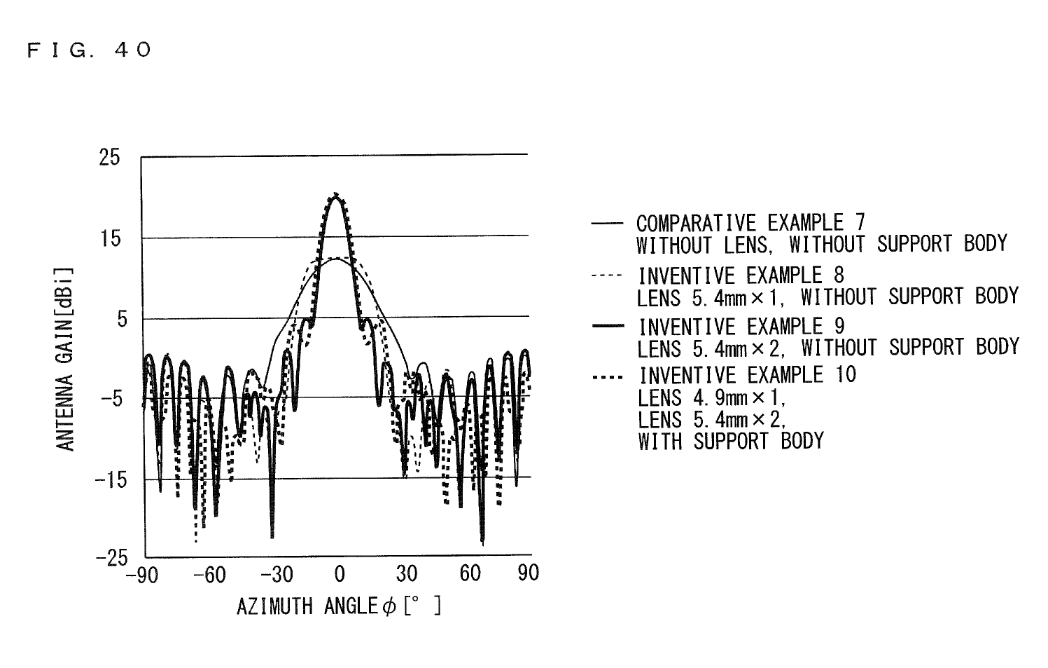

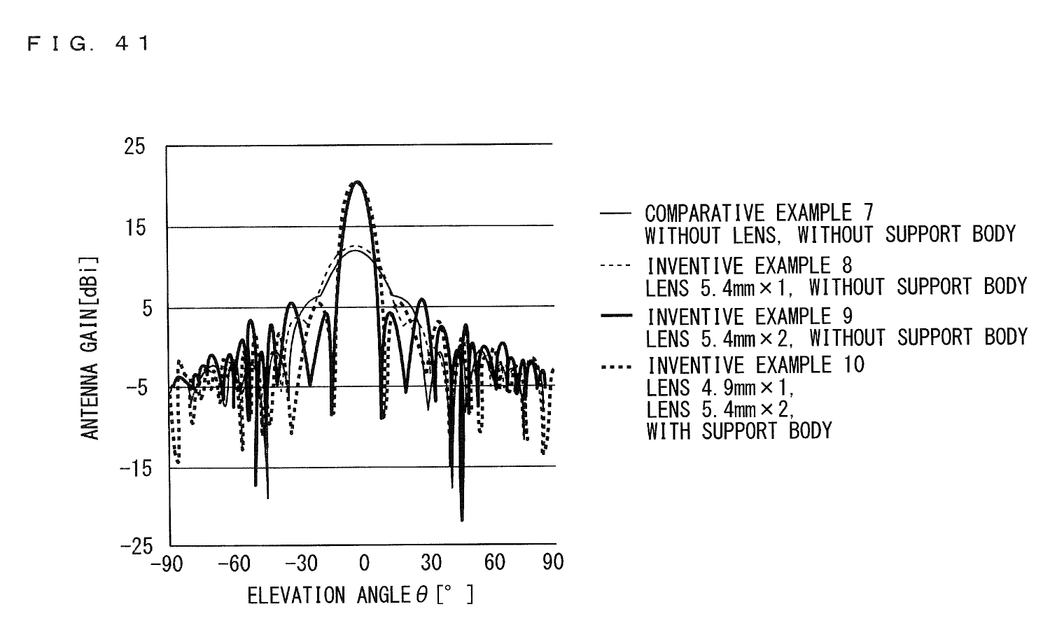

The antenna gain of the antenna module according to the inventive examples 8 to 10 and the comparative example 7 were found by the electromagnetic field simulation. FIGS. 40 and 41 are diagrams showing the results of the electromagnetic field simulation of the antenna gain of the antenna module according to the inventive examples 8 to 10 and the comparative example 7. The ordinate of FIG. 40 indicates the antenna gain [dBi], and the abscissa indicates the azimuth angle φ. The ordinate of FIG. 41 indicates the antenna gain [dBi], and the abscissa indicates the elevation angle θ.

In FIGS. 40 and 41, the antenna gain of the antenna module according to the inventive example 8 is indicated by the thin dotted line. The antenna gain of the antenna module according to the inventive example 9 is indicated by the thick solid line. The antenna gain of the antenna module according to the inventive example 10 is indicated by the thick dotted line. The antenna gain of the antenna module according to the comparative example 7 is indicated by the thin solid line. The maximum antenna gain of the antenna module according to the inventive examples 8 to 10 and the comparative example 7 shown in FIGS. 40 and 41 is shown in Table 4.

TABLE 4

| | MAXIMUM ANTENNA GAIN |
|---|---|
| INVENTIVE EXAMPLE 8 | 12.50 [dBi] |
| INVENTIVE EXAMPLE 9 | 19.81 [dBi] |
| INVENTIVE EXAMPLE 10 | 20.42 [dBi] |
| COMPARATIVE EXAMPLE 7 | 12.42 [dBi] |

As shown in Table 4, the maximum antenna gain of the antenna module according to the inventive examples 8 to 10 were respectively 12.50 dBi, 19.81 dBi and 20.42 dBi. On the other hand, the maximum antenna gain of the antenna module according to the comparative example 7 was 12.42 dBi.

Similarly to the results of the inventive examples 1 to 7 and the comparative examples 1, 2, 5, from the results of the inventive examples 8 to 10 and the comparative example 7, it was confirmed that the maximum antenna gain of the antenna module was improved because the dielectric lens 300 was provided at the antenna module. Further, from the results of the inventive examples 8 to 10, it was confirmed that the maximum antenna gain of the antenna module was further improved because the dielectric lens 300 having an appropriate diameter is further provided at an appropriate position. Further, from the results of the inventive examples 9, 10, it was confirmed that the maximum antenna gain of the antenna module is further improved because the support body 200A is further provided at the antenna module having the plurality of dielectric lenses 300.

Further, as shown in FIGS. 40 and 41, in the antenna module according to the inventive examples 9, 10, better directivity as compared to the antenna module according to the comparative example 7 is obtained.

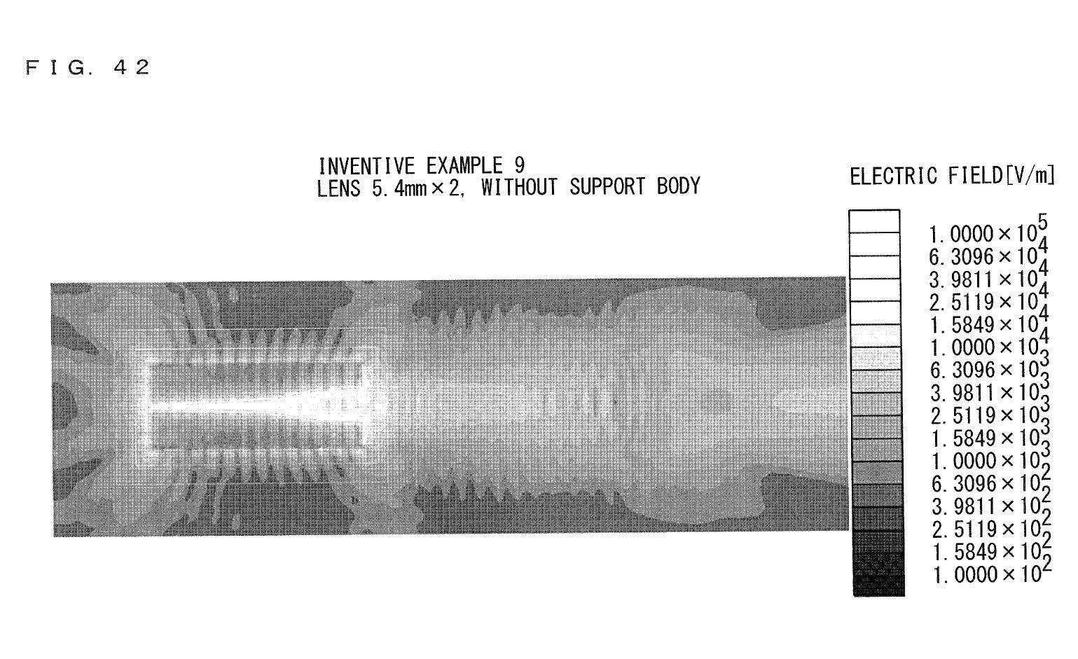

FIG. 42 is a diagram showing the simulation results of the electric field distribution of the electromagnetic wave radiated by the antenna module according to the inventive example 9. As shown in FIG. 42, the plurality of dielectric lens 300 are appropriately arranged at the antenna module, whereby the spread of the electromagnetic wave transmitted by the antenna module is suppressed and the electromagnetic wave paralleled farther can be transmitted.

### (6) Regarding Position of Dielectric Lens

In the antenna module according to the inventive example 11, the dielectric lens 300 is arranged at a first position from the antenna portion 100 of FIG. 21. In the antenna module according to the inventive example 12, the dielectric lens 300 is arranged at a second position that is farther than the first position from the antenna portion 100 of FIG. 21.

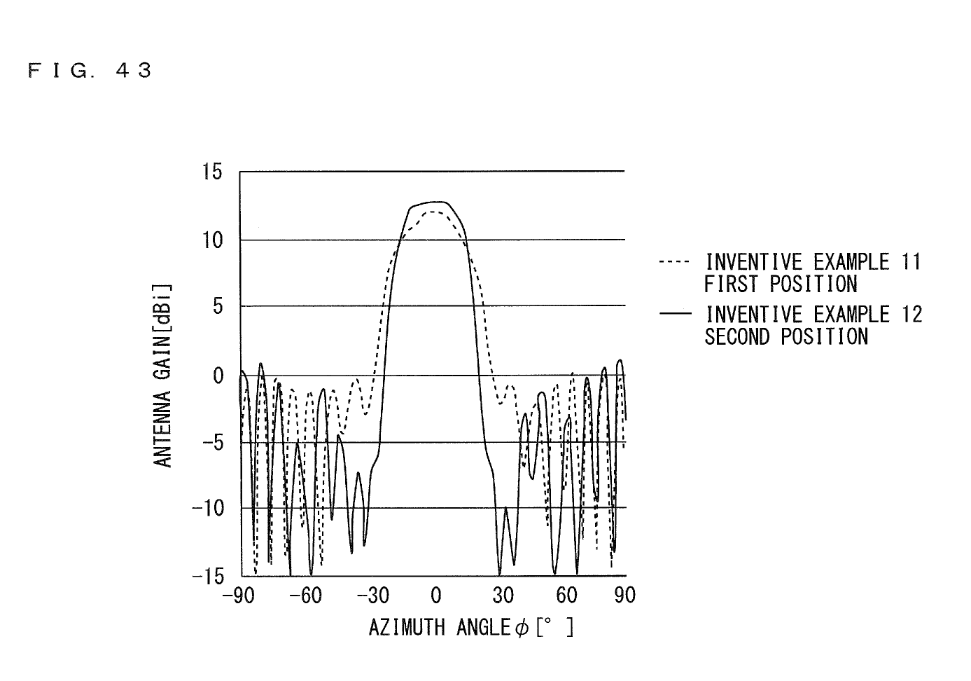

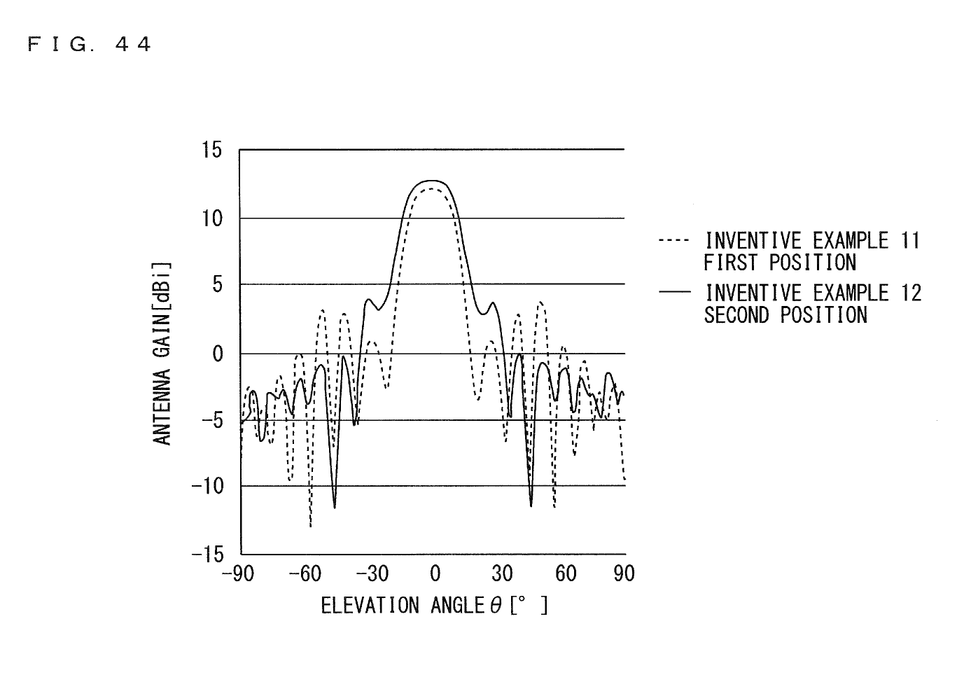

The antenna gain of the antenna module according to the inventive examples 11, 12 were found by the electromagnetic field simulation. FIGS. 43 and 44 are diagrams showing the results of the electromagnetic field simulation of the antenna gain of the antenna module according to the inventive examples 11, 12. The ordinate of FIG. 43 indicates the antenna gain [dBi], and the abscissa indicates the azimuth angle φ. The ordinate of FIG. 44 indicates the antenna gain [dBi], and the abscissa indicates the elevation angle θ.

In FIGS. 43 and 44, the antenna gain of the antenna module according to the inventive example 11 is indicated by the dotted line. The antenna gain of the antenna module according to the inventive example 12 is indicated by the solid line. The maximum antenna gain of the antenna module according to the inventive examples 11, 12 shown in FIGS. 43 and 44 is shown in the Table 5.

TABLE 5

| | MAXIMUM ANTENNA GAIN |
|---|---|
| INVENTIVE EXAMPLE 11 | 11.93 [dBi] |
| INVENTIVE EXAMPLE 12 | 12.53 [dBi] |

As shown in Table 5, the maximum antenna gain of the antenna module according to the inventive examples 11, 12 were respectively 11.93 dBi and 12.53 dBi. From the results of the inventive examples 11, 12, it was confirmed that the maximum antenna gain of the antenna module is improved because the position of the dielectric lens 300 provided at the antenna module is appropriately adjusted.

### [5] Correspondences between Constituent Elements in Claims and Parts in Preferred Embodiments

In the following paragraphs, non-limiting examples of correspondences between various elements recited in the claims below and those described above with respect to various preferred embodiments of the present invention are explained.

Dielectric film 10 is an example of a dielectric film, the main surface is an example of a first surface, the back surface is an example of a second surface, the electrode 20a is an example of an electrode and a first conductor layer, the electrode 20b is an example of an electrode and a second conductor layer and the semiconductor device 30 is an example of a semiconductor device. The support layer 210 is an example of a support layer, the dielectric lens 300 is an example of a lens, the antenna module 500 is an example of an antenna module, the opening OP is an example of a first opening and the opening 242 is an example of a second opening. The tapered slot S is an example of a third opening and width, the insulating layer 220 is an example of an insulating layer, the lens holding member 240 is an example of a lens holding member and the antenna portion 100 is an example of a tapered slot antenna.

In the first embodiment, a portion from the bent portion F1 to the reinforcement plate 213 of the support plates 211, 212, and the reinforcement plate 213 are examples of a first portion, and a portion from the bent portion F1 to the bent portion F4 of the support plates 211, 212, and the reinforcement plates 214, 215 are examples of a second portion. In the second embodiment, the support plates 211, 212 are examples of a first portion, and the projection plates 216, 217 are examples of a second portion.

As each of various constituent elements recited in the claims, various other elements having configurations or functions described in the claims can be also used.

While preferred embodiments of the present invention have been described above, it is to be understood that variations and modifications will be apparent to those skilled in the art without departing the scope and spirit of the present invention. The scope of the present invention, therefore, is to be determined solely by the following claims.

### INDUSTRIAL APPLICABILITY

The present invention can be utilized for transmitting an electromagnetic wave having a frequency in a terahertz band.

I/We claim:

1. An antenna module comprising:
a dielectric film that has first and second surfaces and is made of resin;
an electrode formed on at least one surface of the first and second surfaces of the dielectric film to be capable of receiving and transmitting an electromagnetic wave in a terahertz band;
a semiconductor device mounted on at least one surface of the first and second surfaces of the dielectric film to be electrically connected to the electrode and operable in the terahertz band;
a support layer that has a first portion formed on the first or second surface of the dielectric film and has a second portion; and
a lens supported by the second portion of the support layer, wherein
the second portion is bent with respect to the first portion such that the electromagnetic wave transmitted or received by the electrode permeates through the lens.

2. The antenna module according to claim 1, wherein
the second portion of the support layer has a first opening through which the electromagnetic wave transmitted or received by the electrode passes; and
the lens is supported by the second portion to be positioned at the first opening.

3. The antenna module according to claim 2, further comprising an insulating layer formed on the second portion of the support layer to cover the first opening, wherein
the lens is formed on the insulating layer.

4. The antenna module according to claim 1, further comprising a lens holding member that has a second opening and holds the lens to be positioned at the second opening, wherein
the second portion of the support layer supports the lens holding member such that the electromagnetic wave transmitted or received by the electrode permeates through the lens.

5. The antenna module according to claim 1, wherein
a transmission direction or a receipt direction of the electromagnetic wave by the electrode is parallel to the first and second surfaces of the dielectric film, and
the second portion of the support layer supports the lens such that a light axis of the lens is parallel to the first and second surfaces of the dielectric film.

6. The antenna module according to claim 1, wherein
the electrode includes first and second conductive layers that constitute a tapered slot antenna having a third opening, and
the third opening has a width that continuously or gradually decreases from one end to another end of a set of the first and second conductive layers.

7. The antenna module according to claim 1, wherein
the support layer is formed of a metal material, and
the first portion of the support layer is formed in a region that does not overlap with the electrode on the second surface.

8. A method for manufacturing an antenna module, comprising the steps of:
forming an electrode capable of receiving or transmitting an electromagnetic wave in a terahertz band on at least one surface of first and second surfaces of a dielectric film formed of resin;
forming a first portion of a support layer that includes first and second portions on the first or second surface of the dielectric film;
mounting a semiconductor device operable in the terahertz band on at least one surface of the first and second surfaces of the dielectric film to be electrically connected to the electrode; and
providing a lens to be supported by the second portion of the support layer, and bending the second portion with respect to the first portion such that the electromagnetic wave transmitted or received by the electrode permeates through the lens.

9. A method for manufacturing an antenna module, comprising the steps of:
forming an electrode capable of receiving or transmitting an electromagnetic wave in a terahertz band on at least one surface of first and second surfaces of a dielectric film formed of resin;
forming a first portion of a support layer that includes first and second portions on the first or second surface of the dielectric film;
mounting a semiconductor device operable in the terahertz band on at least one surface of the first and second surfaces of the dielectric film to be electrically connected to the electrode;
bending the second portion with respect to the first portion; and
providing a lens to be supported by the bent second portion, wherein
the step of providing the lens includes arranging the lens such that the electromagnetic wave transmitted or received by the electrode permeates through the lens.
